(19) United States
(12) Patent Application Publication
(10) Pub. No.: US 2024/0414907 A1
(43) Pub. Date: Dec. 12, 2024

(54) MULTI-PORT SRAM CELL WITH DUAL SIDE POWER RAILS

(71) Applicant: Taiwan Semiconductor Manufacturing Company, Ltd., Hsin-Chu (TW)

(72) Inventors: Ping-Wei Wang, Hsin-Chu (TW); Jui-Lin Chen, Taipei City (TW); Yu-Bey Wu, Hsinchu City (TW)

(21) Appl. No.: 18/489,365

(22) Filed: Oct. 18, 2023

Related U.S. Application Data
(60) Provisional application No. 63/506,480, filed on Jun. 6, 2023.

(51) Int. Cl. H10B 10/00

(52) U.S. Cl. CPC H10B 10/125

(57) ABSTRACT

A memory cell includes first and second active regions and first and second gate structures. The first gate structure engages the first and second active regions in forming a first pull-down transistor and a first pull-up transistor, respectively, and the second gate structure engages the first and second active regions in forming a second pull-down transistor and a second pull-up transistor, respectively. A first frontside source/drain contact is disposed above and electrically couples to a first common source/drain region of the first and second pull-down transistors. A first backside via is disposed under and electrically couples to the first common source/drain region. A first backside metal line is disposed under and electrically couples to the first backside via.

### PRIORITY DATA

This application claims priority to U.S. Provisional Patent Application No. 63/506,480 filed on Jun. 6, 2023, the entire disclosure of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Such scaling down has also increased the complexity of processing and manufacturing ICs. For example, aggressive scaling down of IC dimensions has resulted in densely spaced source/drain features and gate structures, and densely spaced source/drain contacts and gate vias formed thereover. In some IC circuits (e.g., memory devices), multilayer interconnect structure providing metal lines for interconnecting power lines and signal lines in and between memory cells of the memory devices are formed over transistors of the memory cells. With ever-decreasing device sizes and densely spaced transistors, some metal lines (e.g., metal lines for power routings) are formed to have reduced dimensions, which may lead to increased parasitic resistance, increased parasitic capacitance, high process risk, and/or poor connection, which may degrade the speed of the memory devices. All those issues present performance, yield, and cost challenges. Therefore, while existing memory devices may be generally adequate for their intended purposes, they are not satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B illustrate a perspective view and a top view of a portion of a memory device, respectively, in accordance with some embodiments of the present disclosure.

FIG. 2 illustrates a cross-sectional view of various layers of a memory device, in accordance with some embodiments of the present disclosure.

FIG. 3 illustrates a circuit schematic for a two-port static random-access memory (SRAM) cell, in accordance with some embodiments of the present disclosure.

FIG. 4 illustrates a layout of a device layer of the two-port SRAM cell as in FIG. 3, in accordance with some embodiments of the present disclosure.

FIGS. 5 and 6 illustrate layouts of various contact and metal layers of the two-port SRAM cell as in FIG. 3, in accordance with some embodiments of the present disclosure.

FIG. 7 illustrates a circuit schematic for a two-port SRAM cell, in accordance with some embodiments of the present disclosure.

FIG. 8 illustrates a layout of a device layer of the two-port SRAM cell as in FIG. 7, in accordance with some embodiments of the present disclosure.

FIGS. 9 and 10 illustrate layouts of various contact and metal layers of the two-port SRAM cell as in FIG. 7, in accordance with some embodiments of the present disclosure.

FIGS. 11, 12, 13, and 14 illustrate various layouts of backside vias and backside metal lines of the two-port SRAM cell as in FIG. 3 or FIG. 7, in accordance with some embodiments of the present disclosure.

FIG. 15 illustrates a layout of an SRAM array based on the two-port SRAM cell as in FIG. 3 or FIG. 7, in accordance with some embodiments of the present disclosure.

FIGS. 16A, 16B, 16C, and 16D illustrate diagrammatic cross-sectional views of a portion of the SRAM array as in FIG. 15, in accordance with some embodiments of the present disclosure.

FIG. 17 illustrates an alternative layout of an SRAM array based on the two-port SRAM cell as in FIG. 3 or FIG. 7, in accordance with some embodiments of the present disclosure.

FIGS. 18A, 18B, 18C, and 18D illustrate diagrammatic cross-sectional views of a portion of the SRAM array as in FIG. 17, in accordance with some embodiments of the present disclosure.

FIGS. 19A, 19B, 19C, 20A, 20B, 20C, 21A, 21B, and 21C illustrate alternative diagrammatic cross-sectional views of a portion of the SRAM array as in FIG. 15 or FIG. 17, in accordance with some other embodiments of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within +/−10% of the number described, unless otherwise specified. For example, the term “about 5 nm” encompasses the dimension range from 4.5 nm to 5.5 nm.

The present disclosure is generally related to static random-access memories (SRAM) devices. More particularly, the present disclosure provides exemplary circuits, in accordance with multi-port SRAM cell layout designs, for providing sufficient layout resources for power routings in multi-port SRAM devices.

SRAM is an electronic data storage device implemented on a semiconductor-based integrated circuit and generally has much faster access times than other types of data storage technologies. SRAM is popular in high-speed communication, image processing and system-on-chip (SOC) applications. A bit can be read from or written into an SRAM cell within a few nanoseconds, while access times for rotating storage such as hard disks is in the range of milliseconds. Among SRAM devices, multi-port SRAM devices have become popular. For example, a two-port (2P) SRAM device allows parallel operation, such as 1R (read) 1W (write), or 2R (read) in one cycle, and therefore has higher bandwidth than a single-port SRAM.

SRAM devices include transistors with metal interconnect structures above the transistors. The metal interconnect structures include metal lines for interconnecting transistor gates and source/drain regions, such as signal lines for routing bit line and word line signals to the cell components, as well as power rails (such as metal lines for voltage sources and ground planes) for providing power to the cell components. Contacts and respective contact vias electrically connect the cell components to the signal lines and the power rails. For example, some of the source/drain (S/D) regions in an SRAM cell are coupled to a power voltage VDD (also referred to as VCC) and/or an electrical ground VSS through source/drain contacts, source/drain contact vias, and respective metal lines in the power rails. Source/drain region(s) may refer to a source or a drain, individually or collectively dependent upon the context.

Conventionally, SRAM devices are built in a stacked-up fashion, having transistors at the lowest level and interconnect structures (contacts, vias, and metal lines) on top of the transistors to provide connectivity to the transistors. Power rails are also above the transistors and may be part of the interconnect structures. With the increasing down-scaling of SRAM devices, so do the power rails. Particularly for multi-port SRAM devices, available layout area becomes limited and metal lines in the power rails are generally formed to have reduced dimensions. This inevitably leads to increased voltage drop across the power rails, as well as increased power consumption, which has become a key issue in further boosting performance of multi-port SRAM devices. Therefore, although existing approaches in semiconductor fabrication have been generally adequate for their intended purposes, they have not been entirely satisfactory in all respects in the context of multi-port SRAM devices. One area of interest is how to form power rails and vias on the backside of SRAM cells with reduced power routing resistance. The power rails formed on both the frontside and the backside of SRAM cells are also referred to as dual side power rails.

Some exemplary embodiments are related to, but not otherwise limited to, multi-gate devices. Multi-gate devices have been introduced in an effort to improve gate control by increasing gate-channel coupling, reduce OFF-state current, and reduce short-channel effects (SCEs). One such multi-gate device that has been introduced is the fin-like field-effect transistor (FinFET). The FinFET gets its name from the fin-like structure which extends from a substrate on which it is formed, and which is used to form the FET channel. Another multi-gate device, introduced in part to address performance challenges associated with the FinFET, is the gate-all-around (GAA) transistor. The GAA transistor gets its name from the gate structure which can extend around the channel region (e.g., a stack of nanosheets) providing access to the channel on four sides. The GAA transistor is compatible with conventional complementary metal-oxide-semiconductor (CMOS) processes and its structure allows it to be aggressively scaled while maintaining gate control and mitigating SCEs. The following disclosure will continue with one or more GAA examples to illustrate various embodiments of the present disclosure. It is understood, however, that the application should not be limited to a particular type of device, except as specifically claimed. For example, aspects of the present disclosure may also apply to implementation based on FinFETs or planar FETs.

The details of the device structures of the present disclosure are described in the attached drawings. The drawings have outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

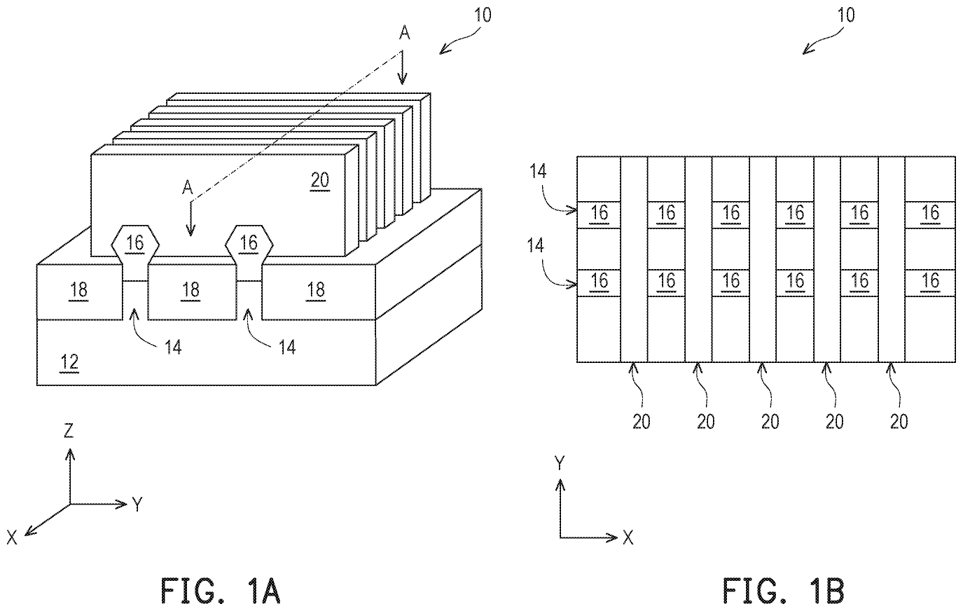

FIGS. 1A and 1B illustrate a perspective view and a top view, respectively, of a portion of an Integrated Circuit (IC) device 10, such as an SRAM device, that is implemented using GAA transistors. Referring to FIG. 1A, the IC device 10 includes a substrate 12. The substrate 12 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GalnAs, GaInP, GaInAsP, and/or other suitable materials. The substrate 12 may be a single-layer material having a uniform composition. Alternatively, the substrate 12 may include multiple material layers having similar or different compositions suitable for IC device manufacturing. In one example, the substrate 12 may be a silicon-on-insulator (SOI) substrate having a semiconductor silicon layer formed on a silicon oxide layer. In another example, the substrate 12 may include a conductive layer, a semiconductor layer, a dielectric layer, other layers, or combinations thereof. Various doped regions, such as source/drain (S/D) regions, may be formed in or on the substrate 12. The doped regions may be doped with n-type dopants, such as phosphorus or arsenic, and/or p-type dopants, such as boron, depending on design requirements. The doped regions may be formed directly on the substrate 12, in a p-well structure, in an n-well structure, in a dual-well structure, or using a raised structure. Doped regions may be formed by implantation of dopant atoms, in-situ doped epitaxial growth, and/or other suitable techniques.

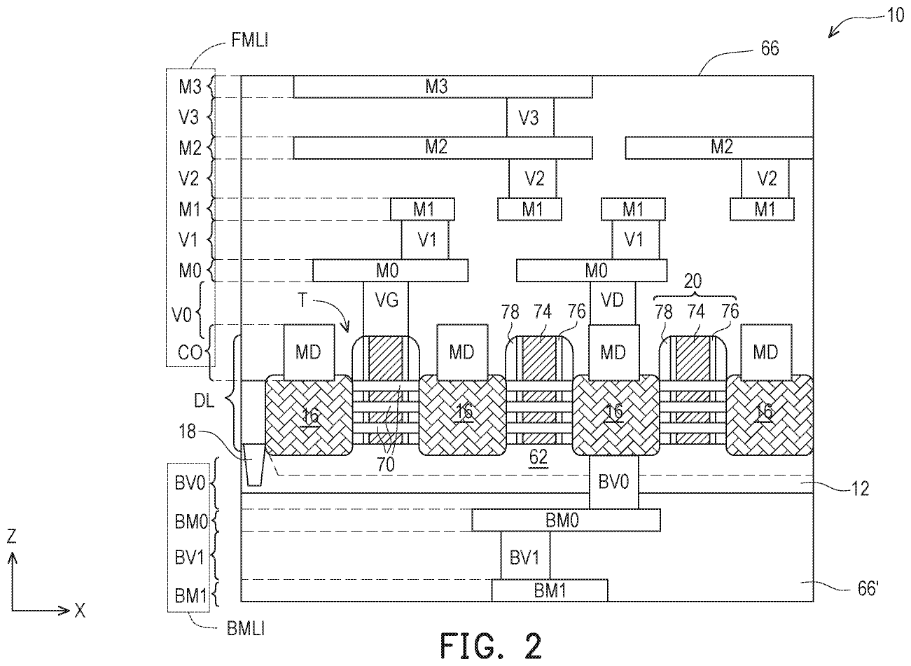

Three-dimensional active regions 14 are formed on the substrate 12. An active region for a transistor refers to the area where a source region, a drain region, and a channel region under a gate structure of the transistor are formed. An active region is also referred to as an “oxide-definition (OD) region” in the context. Each of the active regions 14 includes elongated nanostructures 26 (as shown in FIG. 2) vertically stacked in channel regions defined in the active region and above a fin-shape base. The fin-shape base protrudes upwardly out of the substrate 12. Source/drain features 16 are formed in source/drain regions defined in the active region and over the fin-shape base. The source/drain features 16 abut two opposing ends of the nanostructures 26. The source/drain features 16 may include epi-layers that are epitaxially grown on the fin-shape base.

The IC device 10 further includes isolation structures (or isolation features) 18 formed over the substrate 12. The isolation structures 18 electrically separate various components of the IC device 10. The isolation structures 18 may include silicon oxide, silicon nitride, silicon oxynitride, fluoride-doped silicate glass (FSG), a low-k dielectric material, and/or other suitable materials. In some embodiments, the isolation structures 18 may include shallow trench isolation (STI) features. In one embodiment, the isolation structures 18 are formed by etching trenches in the substrate 12 during the formation of the active regions 14. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 18. Alternatively, the isolation structures 18 may include a multi-layer structure, for example, having one or more thermal oxide liner layers.

The IC device 10 also includes gate structures (or gate stacks) 20 formed over and engaging the active regions 14. The gate structures 20 may be dummy gate structures (e.g., containing an oxide gate dielectric and a polysilicon gate electrode), or they may be high-k metal gate (HKMG) structures that contain a high-k gate dielectric and a metal gate electrode, where the HKMG structures are formed by replacing the dummy gate structures. Though not depicted herein, the gate structures 20 may include additional material layers, such as an interfacial layer, a capping layer, other suitable layers, or combinations thereof.

Referring to FIG. 1B, multiple active regions 14 are oriented lengthwise along the X-direction, and multiple gate structures 20 are oriented lengthwise along the Y-direction, i.e., generally perpendicular to the active regions 14. At intersections of the active regions 14 and the gate structures 20, transistors are formed. In many embodiments, the IC device 10 includes additional features such as gate spacers disposed along sidewalls of the gate structures 20, and numerous other features.

FIG. 2 is a fragmentary diagrammatic cross-sectional view of various layers (levels) that can be fabricated over and under a semiconductor substrate (or wafer) to form a portion of a memory device, such as IC chip 10 of FIGS. 1A and 1B, according to various aspects of the present disclosure. As represented in FIG. 2, the various layers include a device layer DL, a frontside multilayer interconnect structure (FMLI) disposed over the device layer DL, and a backside multilayer interconnect structure (BMLI) disposed under the device layer DL.

Device layer DL includes devices (e.g., transistors, resistors, capacitors, and/or inductors) and/or device components (e.g., doped wells, gate structures, and/or source/drain features). In embodiments represented by FIG. 2, the device layer DL includes substrate 12, doped regions 62 (e.g., n-wells and/or p-wells) disposed in substrate 12, isolation feature 18, and transistors T. In the depicted embodiment, transistors T include suspended channel layers (nanostructures) 70 and gate structures 20 disposed between source/drain features 16, where gate structures 20 wrap and/or surround suspended channel layers 20. Each gate structure 20 has a metal gate stack formed from a gate electrode 74 disposed over a gate dielectric layer 76 and gate spacers 78 disposed along sidewalls of the metal gate stack.

Multilayer interconnect structures FMLI and BMLI electrically couple various devices and/or components of device layer DL, such that the various devices and/or components can operate as specified by design requirements for the memory device. Each of the multilayer interconnect structures FMLI and BMLI may include one or more interconnect layers. In the depicted embodiment, the multilayer interconnect structure FMLI includes a contact interconnect layer (C0 level), a via zero interconnect layer (V0 level), a metal zero interconnect layer (M0 level), a via one interconnect layer (V1 level), a metal one interconnect layer (M1 level), a via two interconnect layer (V2 level), a metal two interconnect layer (M2 level), a via three interconnect layer (V3 level), and a metal three interconnect layer (M3 level). Each of the C0 level, V0 level, M0 level, V1 level, M1 level, V2 Level, M2 level, V3 level, and M3 level may be referred to as a metal level. Metal lines formed at the M0 level may be referred to as M0 metal lines. Similarly, via or metal lines formed at the V1 level, M1 level, V2 level, M2 level, V3 level, and M3 level may be referred to as V1 vias, M1 metal lines, V2 vias, M2 metal lines, V3 vias, and M3 metal lines, respectively. The present disclosure contemplates multilayer interconnect structure FMLI having more or less interconnect layers and/or levels, for example, a total number of N interconnect layers (levels) of the multilayer interconnect structure FMLI with N as an integer ranging from 1 to 10. Each level of multilayer interconnect structure FMLI includes conductive features (e.g., metal lines, metal vias, and/or metal contacts) disposed in one or more dielectric layers (e.g., an interlayer dielectric (ILD) layer and an etch stop layer (ESL)). The dielectric layers of the multilayer interconnect structure FMLI are collectively referred to as a dielectric structure 66. In some embodiments, conductive features at a same level of multilayer interconnect structure FMLI, such as M0 level, are formed simultaneously. In some embodiments, conductive features at a same level of multilayer interconnect structure FMLI have top surfaces that are substantially planar with one another and/or bottom surfaces that are substantially planar with one another.

In embodiments represented by FIG. 2, the C0 level includes source/drain contacts MD disposed in the dielectric structure 66. The source/drain contacts MD may be formed on and in direct contact with silicide layers disposed directly on the source/drain features 16. The V0 level includes gate vias VG disposed on the gate structures and source/drain contact vias VD disposed on the source/drain contacts MD, where gate vias VG connect gate structures to M0 metal lines, source/drain vias V0 connect source/drain contacts MD to M0 metal lines. In some embodiments, the V0 level may also include butted contacts disposed in the dielectric structure 66. The V1 level includes V1 vias disposed in the dielectric structure 66, where V1 vias connect M0 metal lines to M1 metal lines. M1 level includes M1 metal lines disposed in the dielectric structure 66. V2 level includes V2 vias disposed in the dielectric structure 66, where V2 vias connect M1 metal lines to M2 metal lines. M2 level includes M2 metal lines disposed in the dielectric structure 66. V3 level includes V3 vias disposed in the dielectric structure 66, where V3 vias connect M2 metal lines to M3 metal lines.

In the depicted embodiment, the multilayer interconnect structure BMLI includes a backside via zero interconnect layer (BV0 level), a backside metal zero level (BM0 level), a backside via one interconnect layer (BV1 level) and a backside metal one interconnect layer (BM1 level). Each of the BV0 level, BM0 level, BV1 level, and BM1 level may be referred to as a metal level. Metal lines formed at the BM0 level may be referred to as BM0 metal lines. Similarly, via or metal lines formed at the BV0 level, BV1 level and BM1 level may be referred to as BV0 vias, BV1 vias, and BM1 metal lines, respectively. The present disclosure contemplates multilayer interconnect structure BMLI having more or less interconnect layers and/or levels, for example, a total number of M interconnect layers (levels) of the multilayer interconnect structure BMLI with M as an integer ranging from 1 to 10. Each level of multilayer interconnect structure BMLI includes conductive features (e.g., metal lines, metal vias, and/or metal contacts) disposed in one or more dielectric layers (e.g., an interlayer dielectric (ILD) layer and an etch stop layer (ESL)). The dielectric layers of the multilayer interconnect structure BMLI are collectively referred to as a dielectric structure 66′. In some embodiments, conductive features at a same level of multilayer interconnect structure BMLI, such as BM0 level, are formed simultaneously. In some embodiments, conductive features at a same level of multilayer interconnect structure BMLI have top surfaces that are substantially planar with one another and/or bottom surfaces that are substantially planar with one another.

In embodiments represented by FIG. 2, the BV0 level includes vias BV0 formed under the device layer DL. For example, the vias BV0 may include one or more backside source/drain vias formed directly under the source/drain features of the device layer DL and coupled to those source/drain features by way of a silicide layer. The vias BV0 may include one or more backside gate vias formed directly under and in direct contact with the gate structure(s) of the device layer DL. The BM0 level includes BM0 metal lines formed under the BV0 level. The backside gate vias connect gate structures to BM0 metal lines, and the backside source/drain vias connect source/drain features to BM0 metal lines. The BV1 level includes BV1 vias disposed in the dielectric structure 66′, where BV1 vias connect BM0 metal lines to BM1 metal lines. The BM1 level includes BM1 metal lines formed under the BV1 level.

FIG. 2 has been simplified for the sake of clarity to better understand the inventive concepts of the present disclosure. Additional features can be added in the various layers of the memory, and some of the features described can be replaced, modified, or eliminated in other embodiments of the memory. FIG. 2 is merely an example and may not reflect an actual cross-sectional view of the IC chip 10 and/or the SRAM cells 100/100′ that are described in further detail below.

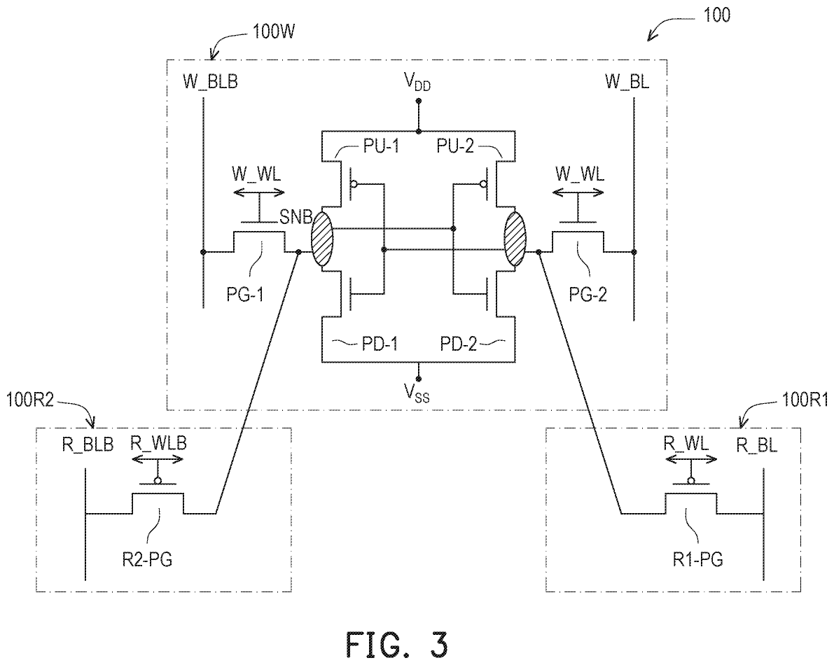

Referring now to FIG. 3, an example circuit schematic for a two-port SRAM cell 100 is shown. The two-port SRAM cell 100 is formed of eight transistors (8T) and also referred to as the two-port 8T SRAM cell 100. The two-port SRAM cell 100 includes a write-port 100W, a first read-port 100R1, and a second read-port 100R2. The write-port 100W includes pull-up transistors PU-1, PU-2, pull-down transistors PD-1, PD-2, and pass-gate transistors PG-1, PG-2. In the illustrated embodiment, transistors PU-1 and PU-2 are p-type transistors, and transistors PG-1, PG-2, PD-1, and PD-2 are n-type transistors.

The drains of the pull-up transistor PU-1 and the pull-down transistor PD-1 are coupled together, and the drains of the pull-up transistor PU-2 and the pull-down transistor PD-2 are coupled together. The transistors PU-1 and PD-1 are cross-coupled with the transistors PU-2 and PD-2 to form a data latch. The gates of the transistors PU-1 and PD-1 are coupled together and to the common drains of the transistors PU-2 and PD-2 to form a storage node SN, and the gates of the transistors PU-2 and PD-2 are coupled together and to the common drains of the transistors PU-1 and PD-1 to form a complementary storage node SNB. Sources of the pull-up transistors PU-1 and PU-2 are coupled to a power voltage VDD (also referred to as VCC), and the sources of the pull-down transistors PD-1 and PD-2 are coupled to a voltage VSS, which may be an electrical ground in some embodiments.

The storage node SN of the data latch is coupled to a bit line W_BL of the write-port 100W through the pass-gate transistor PG-2, and the complementary storage node SNB is coupled to a complementary bit line W_BLB of the write-port 100W through the pass-gate transistor PG-1. The storage node SN and the complementary storage node SNB are complementary nodes that are often at opposite logic levels (logic high or logic low). Gates of the pass-gate transistors PG-1 and PG-2 are coupled to a word line W_WL of the write-port 100W.

The first read-port 100R1 of the SRAM cell 100 includes a first read-port pass-gate transistor (R1-PG) coupled between the bit line R_BL and the storage node SN (or to the gates of the transistors PU-1 and PD-1). The gate of the first read-port pass-gate transistor R1-PG is coupled to a word line R_WL of the first read-port 100R1. The second read-port 100R2 of the SRAM cell 100 includes a second read-port pass-gate transistor (R2-PG) coupled between the complementary bit line R_BLB and the complementary storage node SNB (or to the gates of the transistors PU-2 and PD-2). The gate of the second read-port pass-gate transistor R2-PG is coupled to a complementary word line R_WLB of the second read-port 100R2. In the illustrated embodiment, the transistors R1-PG and R2-PG are p-type transistors. That is, in the two-port SRAM cell 100, the pass-gate transistors in a write-port are n-type transistors, and the pass-gate transistors in read-ports are p-type transistors.

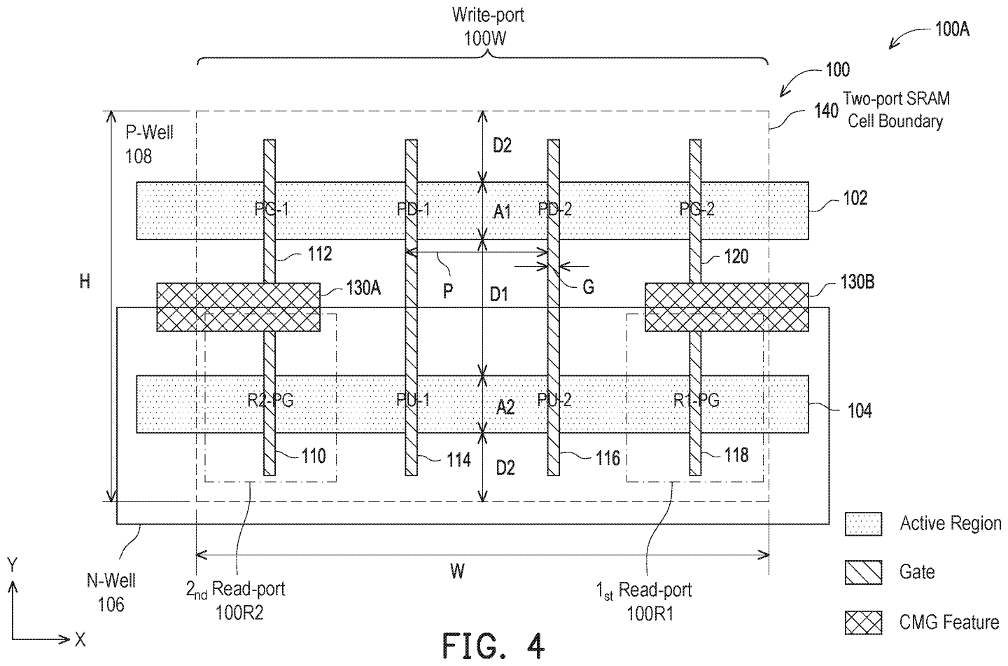

FIG. 4 illustrates a simplified diagrammatic layout 100A at the device layer (DL) of the two-port SRAM cell 100, which includes the write-port 100W, the first read-port 100R1, and the second read-port 100R2. The write-port 100W includes the transistors PG-1, PG-2, PU-1, PU-2, PD-1, and PD-2. The first read-port 100R1 includes the transistor R1-PG. The second read-port 100R2 includes the transistor R2-PG. For reasons of visual clarity and simplicity, the active regions and the gate structures of these transistors, together with some gate-cut features, are shown in FIG. 4, while the interconnection components such as contacts, vias, and metal lines are omitted from FIG. 4.

As shown in FIG. 4, the two-port SRAM cell 100 includes active regions 102 and 104. The active regions 102, 104 each extend lengthwise in the X-direction in FIG. 4. In the illustrated embodiment, the active regions 102, 104 may each include (or may be implemented as) the nanostructures 70 of FIG. 2 discussed above. In other embodiments, the active regions 102, 104 may include fin structures as well. The active region 102 are a components of the write-port 100W, and the active region 104 has a side portion as a component of the first read-port 100R1, a middle portion as a component of the write-port 100W, and another side portion as a component of the second read-port 100R2. In other words, the active region 104 is shared by the two read-ports 100R1, 100R2 and the write-port 100W. In the illustrated embodiment, the active region 104 belong to the transistors PU-1, PU-2, R1-PG, R2-PG, which are PMOS devices. As such, the active region 104 is formed over an N-well 106. Meanwhile, the active region 102 belongs to the transistors PG-1, PD-1, PD-2, PG-2, which are NMOS devices. As such, the active region 102 is formed over a P-well 108 (or a P-type substrate).

As shown in FIG. 4, the two-port SRAM cell 100 further includes gate structures 110, 112, 114, 116, 118, and 120. The gate structures 110-120 each extend lengthwise in the Y-direction in FIG. 4. The gate structures 110-120 may each include (or may be implemented as) the gate structures 20 of FIG. 2 discussed above. The gate structures 112, 114, 116, and 120 are components of the write-port 100W. The gate structure 118 is a component of the first read-port 100R1. The gate structure 110 is a component of the second read-port 100R2. The gate structures 114, 116 each extend through the two active regions 102, 104. As such, the gate structure 114 is shared by the transistors PD-1 and PU-1, and the gate structure 116 is shared by the transistors PD-2 and PU-2.

Still referring to FIG. 4, the two-port SRAM cell 100 further includes a plurality of gate-cut dielectric features extending lengthwise along the X-direction, including dielectric features 130A, 130B (collectively, dielectric features 130). In the illustrated embodiment, the dielectric feature 130A is disposed between the active regions 102, 104 and abuts the gate structure 110 and the gate structure 112. The dielectric feature 130A divides an otherwise continuous gate structure into two isolated segments corresponding to the gate structure 110 and the gate structure 112. Similarly, the dielectric feature 130B is disposed between the active regions 102, 104 and abuts the gate structure 118 and the gate structure 120. The dielectric feature 130B divides an otherwise continuous gate structure into two isolated segments corresponding to the gate structure 118 and the gate structure 120. Each of the dielectric features 130 is formed by filling a corresponding cut-metal-gate (CMG) trench in the position of the dielectric features. The dielectric features 130 are also referred to as CMG features. In the illustrated embodiment, each of the dielectric features 130A, 130B is disposed above an interface between the N-well 106 and the P-well 108.

A CMG process refers to a fabrication process where after a metal gate (e.g., a high-k metal gate or HKMG) replaces a dummy gate structure (e.g., a polysilicon gate), the metal gate is cut (e.g., by an etching process) to separate the metal gate into two or more gate segments. Each gate segment functions as a metal gate for an individual transistor. An isolation material is subsequently filled into trenches between adjacent portions of the metal gate. These trenches are referred to as cut-metal-gate trenches, or CMG trenches, in the present disclosure. The dielectric material filling a CMG trench for isolation is referred to as a CMG feature. To ensure a metal gate would be completely cut, a CMG feature often further extends into adjacent areas, such as dielectric layers filling space between the metal gates. A CMG feature often have an elongated shape in a top view.

Still referring to FIG. 4, a boundary 140 of the two-port SRAM cell 100 is illustrated in FIG. 4 using broken lines. Note that some of the active regions and gate structures may extend beyond the illustrated boundary 140, since these active regions and gate structures may also form components of other adjacently located SRAM cells as well. The boundary 140 is longer in the X-direction than in the Y-direction. In other words, the boundary 140 may be rectangular. The first dimension of the boundary 140 along the X-direction is denoted as a cell width W, and the second dimension of the boundary 140 along the Y-direction is denoted as a cell height H. Where the two-port SRAM cell 100 is repeated in a memory array, the cell width W may represent and be referred to as a memory cell pitch in the memory array along the X-direction, and the cell height H may represent and be referred to as a memory cell pitch in the memory array along the Y-direction.

The cell size of the two-port SRAM cell 100 is W×H, in which the cell width W is about 4 times a poly pitch (an edge-to-edge distance or center-to-center distance between two adjacent gate structures along the X-direction) and the cell height H is about 2 times an isolation pitch (e.g., a center-to-center distance between two adjacent STI features along the Y-direction). Denoting an area of one poly pitch times one isolation pitch as a unit area, each unit area includes an intersection of a gate structure and an active region, and the two-port SRAM cell 100 utilizes a cell size of about 8 times a unit area in accommodating the eight transistors, namely the transistors PG-1, PG-2, PU-1, PU-2, PD-1, PD-2, R1-PG, and R2-PG. The area utilization rate is high in the layout 100A, because each transistor formed at an intersection of a gate structure and an active region is a functional transistor and there is no non-functional transistor in the layout 100A.

FIG. 4 also illustrates dimensions of some features in the layout of the SRAM cell 100. The active region 102 has a width denoted as A1, the active region 104 has a width denoted as A2. Each of the gate structures 110-120 has a critical dimension (CD) or gate width denoted as G. In the illustrated embodiment, the gate structures 110-120 are evenly distributed along the X-direction. An edge-to-edge (or center-to-center) distance between two adjacent gate structures along the X-direction is a gate pitch (or poly pitch) denoted as P. A distance (along the Y-direction) between opposing edges of the active regions 102, 104 is denoted as D1. A distance (along the Y-direction) between an edge of the active region 102 or 104 and a respective closest edge of the boundary 140 is denoted as D2. Therefore, the cell height H of the SRAM cell 100 is A1+A2+D1+2×D2. In some embodiments, G ranges from about 10 nm to about 20 nm; A1 ranges from about 11 nm to about 35 nm; A2 ranges from about 11 nm to about 35 nm; D1 ranges from about 30 nm to about 80 nm; and D2 ranges from about 15 nm to about 40 nm. A1 and A2 may be the same or different to balance speeds among write-port and read-port. A ratio between A2 and A1 (A2/A1) may range from about 0.3 to about 3.5.

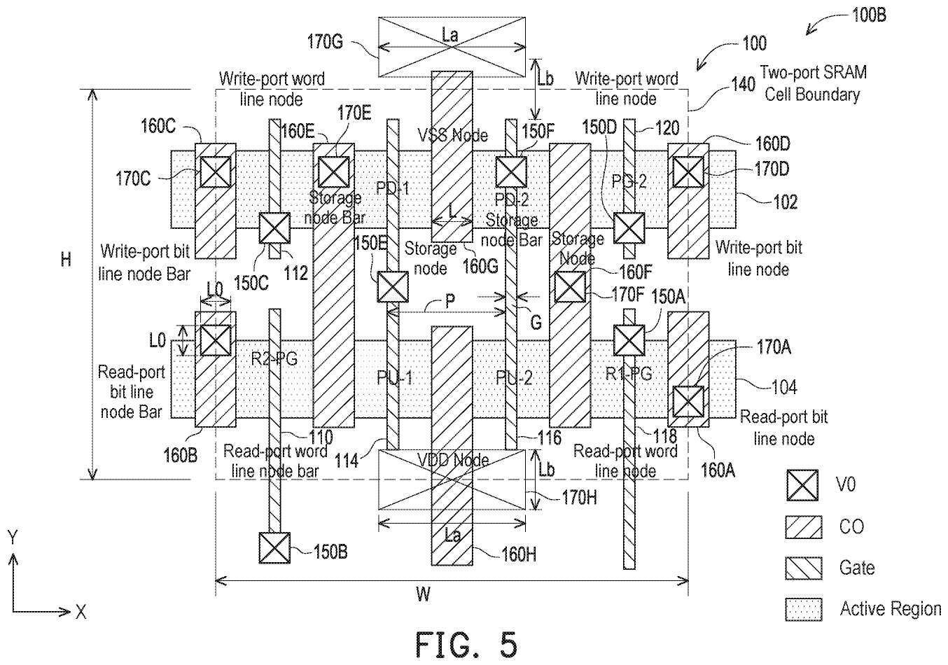

FIG. 5 illustrates a simplified diagrammatic layout 100B at the contact level (C0) and the via zero (V0) level of the two-port SRAM cell 100. Also, for reasons of aiding visual clarity, some features in the layout 100A devoted to the device layer (DL) are reproduced in FIG. 5, such as the active regions 102, 104, the gate structures 110-120, and the cell boundary 140, while numerous other features are omitted in FIG. 5.

A gate contact 150A electrically connects a gate of the first read-port pass-gate transistor R1-PG (formed by the gate structure 118) to the read-port word line R_WL. A gate contact 150B electrically connects a gate of the second read-port pass-gate transistor R2-PG (formed by the gate structure 110) to the read-port complementary word line R_WLB. A gate contact 150C electrically connects a gate of the write-port pass-gate transistor PG-1 (formed by the gate structure 112) to the write-port word line W_WL. A gate contact 150D electrically connects a gate of the write-port pass-gate transistor PG-2 (formed by the gate structure 120) to the write-port word line W_WL. A gate contact 150E electrically connects a gate of the write-port pull-down transistor PD-1 (formed by the gate structure 114) and a gate of the write-port pull-up transistor PU-1 (also formed by the gate structure 114) to the storage node SN. A gate contact 150F electrically connects a gate of the write-port pull-down transistor PD-2 (formed by the gate structure 116) and a gate of the write-port pull-up transistor PU-2 (also formed by the gate structure 116) to the complementary storage node SNB.

A source/drain contact 160A and a source/drain contact via 170A landing thereon electrically connect a source region of the first read-port pass-gate transistor R1-PG to the read-port bit line R_BL. A source/drain contact 160B and a source/drain contact via 170B landing thereon electrically connect a source region of the second read-port pass-gate transistor R2-PG to the read-port complementary bit line R_BLB. A source/drain contact 160C and a source/drain contact via 170C landing thereon electrically connect a source region of the write-port pass-gate transistor PG-1 to the write-port complementary bit line W_BLB. A source/drain contact 160D and a source/drain contact via 170D landing thereon electrically connect a source region of the write-port pass-gate transistor PG-2 to the write-port bit line W_BL. A source/drain contact 160E and a source/drain contact via 170E landing thereon electrically connect a common drain region of the write-port pass-gate transistor PG-1 and the write-port pull-down transistor PD-1 together with a common drain region of the write-port pull-up transistor PU-1 and the second read-port pass-gate transistor R2-PG to the complementary storage node SNB. A source/drain contact 160F and a source/drain contact via 170F landing thereon electrically connect a common drain region of the write-port pass-gate transistor PG-2 and the write-port pull-down transistor PD-2 together with a common drain region of the write-port pull-up transistor PU-2 and the first read-port pass-gate transistor R1-PG to the storage node SN. A source/drain contact 160G and a source/drain contact via 170G landing thereon electrically connect a common source region of the write-port pull-down transistor PD-1 and the write-port pull-down transistor PD-2 to the electrical ground node Vss. A source/drain contact 160H and a source/drain contact via 170H landing thereon electrically connect a common source region of the write-port pull-up transistor PU-1 and the write-port pull-up transistor PU-2 to the power voltage node VDD. In the illustrated embodiment, the source/drain contacts 360A-360H each are elongated and have a longitudinal direction in the Y-direction, which is parallel to the extending directions of gate structures.

Still referring to FIG. 5, the gate contacts 150A-F and the source/drain contact vias 170A-F may have the same size in a top view. For example, each of the gate contacts 150A-F and the source/drain contact vias 170A-F may have a square shape with the same edge length L0 in the X-direction and in the Y-direction. Further in the illustrated embodiment, each of the source/drain contacts 160A-H may have the same width L measured in the X-direction, and the edge length L0 may be smaller than the width L. As a comparison, each of the source/drain contact vias 170G and 170H has a larger size, such as a first dimension La measured in the X-direction and a second dimension Lb measured in the Y-direction with La>L0 and Lb>L0. In some embodiments, the first dimension La may be larger than the width L. In furtherance of some embodiments, edges of the source/drain contact vias 170G and 170H may extend beyond outer edges of the gate structure 114 and the gate structure 116. State differently, the first dimension La may be larger than a sum of the poly pitch P and the gate width G (La>P+G). A portion of the gate structure 114 and a portion of the gate structure 116 may be directly under the source/drain contact vias 170G and 170H. In some embodiments, a range of La/L0 is from about 1 to about 5, and a range of Lb/L0 is from about 1 to about 5. In some embodiments, a range of La/G is from about 1 to about 5, and a range of Lb/G is from about 1 to about 5. In some embodiments, a range of La/L is from about 1 to about 5, and a range of Lb/L is from about 1 to about 5. The source/drain contact vias 170G and 170H are electrically connected to the electrical ground node and power voltage node, respectively, whose resistances contribute more impacts to an SRAM cell's speed than other source/drain contact vias and gate contacts. The larger size of the source/drain contact vias 170G and 170H reduces respective source/drain contact via resistance and effectively improves circuit speed.

Also shown in FIG. 5, the storage node SN includes the gate contact 150E and the source/drain contact via 170F positioned on two opposing sides of the gate structure 116. As to discuss in further detail below, a metal line at the M0 level extends in the X-direction to across the gate structure 116 and connects the gate contact 150E and the source/drain contact via 170F. In other words, an M0 metal line hangs over the gate structure 116 and provide the function of cross coupling between the gate contact 150E and the source/drain contact via 170F. Therefore, in the layout 100B, the gate contact 150E and the source/drain contact via 170F are positioned as being level in the Y-direction, such that a metal line extending in the X-direction may connect both. Similarly, the complementary storage node (storage node bar) SNB includes the gate contact 150F and the source/drain contact via 170E positioned on two opposing sides of the gate structure 114. As to discuss in further detail below, another metal line at the M0 level extends in the X-direction to across the gate structure 114 and connects the gate contact 150F and the source/drain contact via 170E. In other words, another M0 metal line hangs over the gate structure 114 and provide the function of cross coupling between the gate contact 150F and the source/drain contact via 170E. Therefore, in the layout 100B, the gate contact 150F and the source/drain contact via 170E are positioned as being level in the Y-direction, such that a metal line extending in the X-direction may connect both.

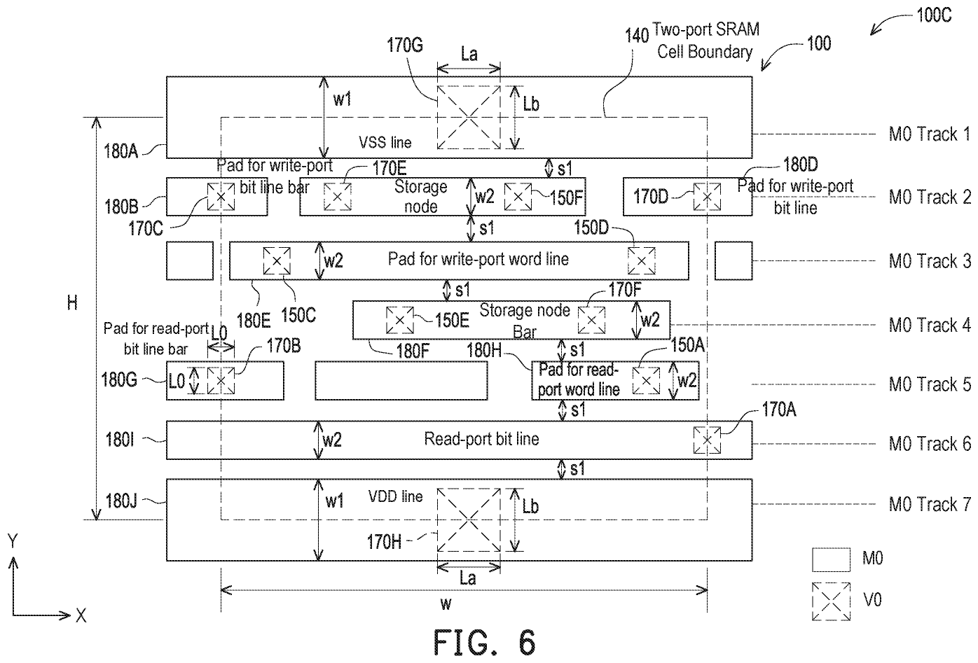

FIG. 6 illustrates a simplified diagrammatic layout 100C at the metal zero (M0) level of the two-port SRAM cell 100. Also, for reasons of aiding visual clarity, the gate contacts 150A-F and source/drain contact vias 170A-H at the via zero (V0) level are reproduced in FIG. 6, while numerous other features are omitted in FIG. 6.

At the M0 level, the SRAM cell 100 includes a plurality of metal tracks arranged in parallel. Particularly, in the illustrated embodiment of the layout 100C, the SRAM cell 100 includes seven metal tracks arranged in order from first (M0 Track 1) to seventh (M0 Track 7) along the Y-direction. The center lines of the metal tracks are represented by the dotted lines in FIG. 6. A distance between the center lines of the adjacent metal tracks is denoted as the metal track pitch.

One metal track may include a single metal line extending through the entire SRAM cell 100 along the X-direction. Such a metal line is denoted as a global metal line. Alternatively, one metal track may include one or more metal lines that do not extend through the entire SRAM cell 100. Such a metal line is denoted as a local metal line, or referred to as an island, a pad, or a landing pad. In the layout 100C, the first metal track “M0 Track 1” includes a global metal line 180A, which is a VSS line electrically coupled to the source/drain contact via 170G. The VSS line 180A is disposed on the upper boundary line of the SRAM cell 100 and shared with an adjacent SRAM cell. Disposed on the upper boundary line of the SRAM cell 100, the source/drain contact via 170G is also shared by the two adjacent SRAM cells. The second metal track “M0 Track 2” includes three local metal lines 180B, 180C, and 180D. The local metal line 180B provides a pad for the write-port complimentary bit line (W_BLB). The local metal line 180B extends beyond a left edge of the SRAM cell 100 and may be shared with an adjacent SRAM cell. The local metal line 180C is fully within the SRAM cell 100, which belongs to the storage node (SN) and provides cross-coupling between the gate contact 150F and the source/drain contact via 170E. As discussed above, the local metal line 180C crosses over the gate structure 114. The local metal line 180D provides a pad for the write-port bit line (W_BL). The local metal line 180D extends beyond a right edge of the SRAM cell 100 and may be shared with an adjacent SRAM cell. The third metal track “M0 Track 3” includes a local metal line 180E as a pad for the write-port word line (W_WL). The local metal line 180E is fully within the SRAM cell 100 and electrically connects to the gate contact 150C and the gate contact 150D. The fourth metal track “M0 Track 4” includes a local metal line 180F, which belongs to the complementary storage node (SNB). The local metal line 180F is fully within the SRAM cell 100 and provides cross-coupling between the gate contact 150E and the source/drain contact via 170F. As discussed above, the local metal line 180F crosses over the gate structure 116. The fifth metal track “M0 Track 5” includes a local metal line 180G and a local metal line 180H. The local metal line 180G provides a pad for the read-port complimentary bit line (R_BLB). The local metal line 180G extends beyond a left edge of the SRAM cell 100 and may be shared with an adjacent SRAM cell. The local metal line 180H provides a pad for the read-port word line (R_WL). The local metal line 180H extends beyond a right edge of the SRAM cell 100 and may be shared with an adjacent SRAM cell. There may be a non-functional (electrically floating) pad inserted between the local metal line 180G and the local metal line 180H for improving uniformity of metal line density. The sixth metal track “M0 Track 6” includes a global metal line 1801, which is a read-port bit line electrically coupled to the source/drain contact via 170A. The seventh metal track “M0 Track 7” includes a global metal line 180J, which is a VDD line electrically coupled to the source/drain contact via 170H. The VDD line 180J is disposed on the lower boundary line of the SRAM cell 100 and may be shared with an adjacent SRAM cell. Disposed on the lower boundary line of the SRAM cell 100, the source/drain contact via 170H is also shared by the two adjacent SRAM cells.

A width of the VSS line 180A is denoted as w1 with one half of w1 in one SRAM cell and another half of w1 in the adjacent SRAM cell. A width of the VDD line 180J may be substantially the same as the VSS line 180A with one half of w1 in one SRAM cell and another half of w1 in the adjacent SRAM cell. The other M0 metal lines 180B-I may each have the same width denoted as w2. The spacing between two adjacent M0 metal lines may be uniform and denoted as s1. Thus, the SRAM cell height H equals w1+5*w2+6*s1.

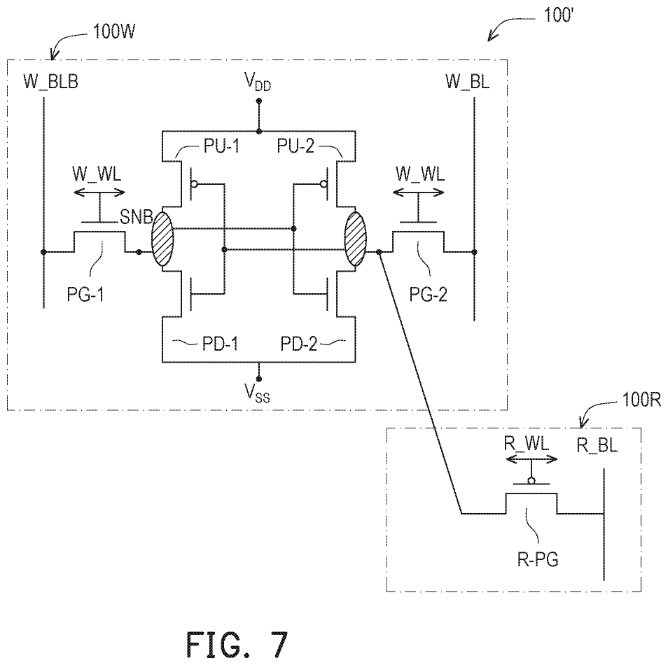

Referring now to FIG. 7, an example circuit schematic for another two-port SRAM cell 100′ is shown. The two-port SRAM cell 100′ is formed of seven transistors (7T) and also referred to as the two-port 7T SRAM cell 100′. Many aspects of the two-port SRAM cell 100′ are similar to those of the two-port SRAM cell 100. Some reference numerals are repeated for ease of understanding. The two-port SRAM cell 100′ includes a write-port 100W and a read-port 100R. The write-port 100W includes pull-up transistors PU-1, PU-2, pull-down transistors PD-1, PD-2, and pass-gate transistors PG-1, PG-2. In the illustrated embodiment, transistors PU-1 and PU-2 are p-type transistors, and transistors PG-1, PG-2, PD-1, and PD-2 are n-type transistors.

The drains of the pull-up transistor PU-1 and the pull-down transistor PD-1 are coupled together, and the drains of the pull-up transistor PU-2 and the pull-down transistor PD-2 are coupled together. The transistors PU-1 and PD-1 are cross-coupled with the transistors PU-2 and PD-2 to form a data latch. The gates of the transistors PU-1 and PD-1 are coupled together and to the common drains of the transistors PU-2 and PD-2 to form a storage node SN, and the gates of the transistors PU-2 and PD-2 are coupled together and to the common drains of the transistors PU-1 and PD-1 to form a complementary storage node SNB. Sources of the pull-up transistors PU-1 and PU-2 are coupled to a power voltage VDD (also referred to as VCC), and the sources of the pull-down transistors PD-1 and PD-2 are coupled to a voltage VSS, which may be an electrical ground in some embodiments.

The storage node SN of the data latch is coupled to a bit line W_BL of the write-port 100W through the pass-gate transistor PG-2, and the complementary storage node SNB is coupled to a complementary bit line W_BLB of the write-port 100W through the pass-gate transistor PG-1. The storage node SN and the complementary storage node SNB are complementary nodes that are often at opposite logic levels (logic high or logic low). Gates of the pass-gate transistors PG-1 and PG-2 are coupled to a word line W_WL of the write-port 100W.

The read-port 100R of the SRAM cell 100′ includes a read-port pass-gate transistor (R-PG) coupled between the bit line R_BL and the storage node SN (or to the gates of the transistors PU-1 and PD-1). The gate of the read-port pass-gate transistor R-PG is coupled to a word line R_WL of the read-port 100R. In the illustrated embodiment, the transistor R-PG is a p-type transistor. That is, in the two-port SRAM cell 100′, the pass-gate transistors in a write-port are n-type transistors, and the pass-gate transistor in a read-port is a p-type transistor.

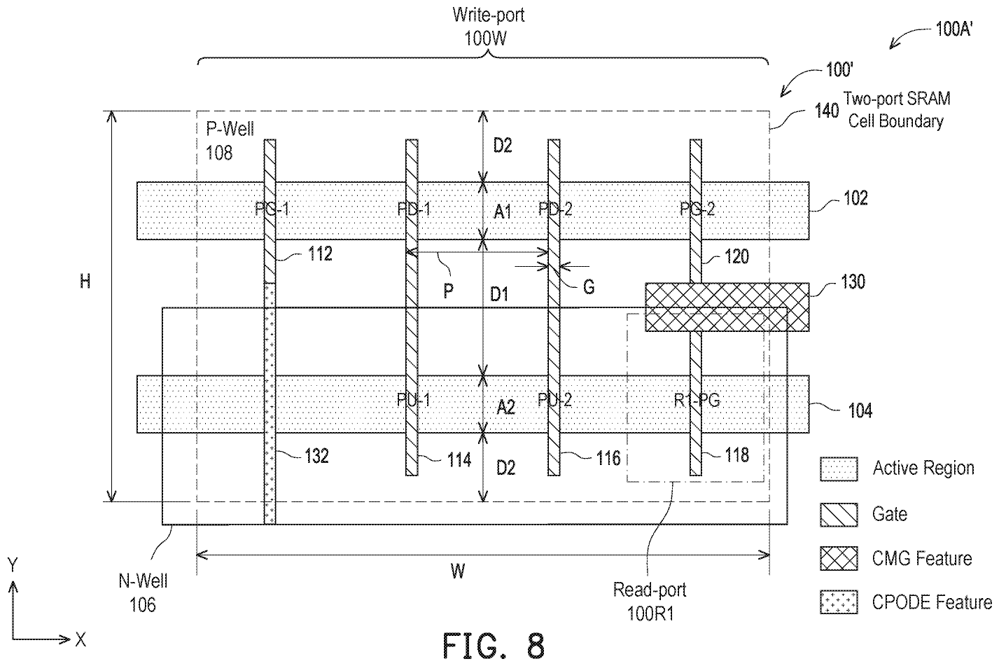

FIG. 8 illustrates a simplified diagrammatic layout 100A′ of the device layer (DL) of the two-port SRAM cell 100′, which includes the write-port 100W and the read-port 100R. The write-port 100W includes the transistors PG-1, PG-2, PU-1, PU-2, PD-1, and PD-2. The read-port 100R includes the transistor R-PG. For reasons of visual clarity and simplicity, the layout 100A′ includes active regions and gate structures of those transistors in the SRAM cell 100′, together with some gate-cut features, while numerous other features in or above the device layer DL such as contacts, vias, and metal lines are not included in the layout 100A′.

As shown in FIG. 8, the two-port SRAM cell 100′ includes active regions 102 and 104. The active regions 102, 104 each extend lengthwise in the X-direction in FIG. 8. In the illustrated embodiment, the active regions 102, 104 may each include (or may be implemented as) the nanostructures 70 of FIG. 2 discussed above. In other embodiments, the active regions 102, 104 may include fin structures as well. The active region 102 are a components of the write-port 100W, and the active region 104 has a side portion as a component of the read-port 100R and rest portion as a component of the write-port 100W. In other words, the active region 104 is shared by the read-port 100R and the write-port 100W. In the illustrated embodiment, the active region 104 belong to the transistors PU-1, PU-2, R-PG, which are PMOS devices. As such, the active region 104 is formed over an n-well 106. Meanwhile, the active region 102 belongs to the transistors PG-1, PD-1, PD-2, PG-2, which are NMOS devices. As such, the active region 102 is formed over a p-well 108 (or a p-type substrate).

As shown in FIG. 8, the two-port SRAM cell 100 further includes gate structures 112, 114, 116, 118, and 120. The gate structures 112-120 each extend lengthwise in the Y-direction in FIG. 8. The gate structures 112-120 may each include (or may be implemented as) the gate structures 20 of FIG. 2 discussed above. The gate structures 112, 114, 116, and 120 are components of the write-port 100W. The gate structure 118 is a component of the read-port 100R. The gate structures 114, 116 each extend through the two active regions 102, 104. As such, the gate structure 114 is shared by the transistors PD-1 and PU-1, and the gate structure 116 is shared by the transistors PD-2 and PU-2.

Still referring to FIG. 8, the two-port SRAM cell 100′ further includes a plurality of gate-cut dielectric features, including a first dielectric feature 130 extending lengthwise along the X-direction and a second dielectric feature 132 extending lengthwise along the Y-direction. In the illustrated embodiment, the dielectric feature 130 is disposed between the active regions 102, 104 and abuts the gate structure 118 and the gate structure 120. The dielectric feature 130 divides an otherwise continuous gate structure line into two isolated segments corresponding to the gate structure 118 and the gate structure 120. The dielectric feature 130 is formed by filling a corresponding cut-metal-gate (CMG) trench in the position of the dielectric feature 130. The dielectric feature 130 is also referred to as a CMG feature. In the illustrated embodiment, the dielectric feature 130 is disposed above an interface between the n-well 106 and the p-well 108.

The gate-cut feature 132 is formed in a continuous-poly-on-diffusion-edge (CPODE) process and also referred to as a CPODE feature. For purposes of this disclosure, a “diffusion edge” may be equivalently referred to as an active edge, where for example an active edge abuts adjacent active regions. Before the CPODE process, the active edge may include a dummy GAA structure having a dummy gate structure (e.g., a polysilicon gate) and a plurality of vertically stacked nanostructures as channel layers. In addition, inner spacers may be disposed between adjacent nanostructures at lateral ends of the nanostructures. In various examples, source/drain epitaxial features are disposed on either side of the dummy GAA structure, such that the adjacent source/drain epitaxial features are in contact with the inner spacers and nanostructures of the dummy GAA structure. The subsequent CPODE etching process removes the dummy gate structure and the channel layers from the dummy GAA structure to form a CPODE trench. The dielectric material filling a CPODE trench for isolation is referred to as a CPODE feature. In some embodiments, after the CPODE features are formed, the remaining dummy gate structures are replaced by metal gate structures in a replacement gate (gate-last) process. State differently, in some embodiments, the CPODE feature replaces a portion of the otherwise continuous gate structure and is confined between the opposing gate spacers of the replaced portion of the gate structure. As a comparison, the CMG feature is formed after the formation of the metal gate structure line and truncates the otherwise continuous gate structure line and extends into adjacent areas of the gate structure, while the CPODE feature is formed after the formation of the polysilicon gate structure line and prior to the formation of the metal gate structure and extends aligned with the metal gate structure. In FIG. 8, the CPODE feature 132 abuts the gate structure 112 and is aligned with the gate structure 112. The CPODE feature 132 extends along the Y-direction and across the n-well 106 into another p-well 108 of an adjacent SRAM cell. That is, two adjacent SRAM cells may share the CPODE feature 132. Further, the CPODE feature 132 may extend downwardly deeper into the underneath substrate than the CMG feature 130, in some embodiments.

Still referring to FIG. 8, a boundary 140 of the two-port SRAM cell 100′ is illustrated in FIG. 8 using broken lines. Note that some of the active regions and gate structures may extend beyond the illustrated boundary 140, since these active regions and gate structures may also form components of other adjacently located SRAM cells as well. The boundary 140 is longer in the X-direction than in the Y-direction. In other words, the boundary 140 may be rectangular. The first dimension of the boundary 140 along the X-direction is denoted as a cell width W, and the second dimension of the boundary 140 along the Y-direction is denoted as a cell height H. Where the two-port SRAM cell 100′ is repeated in a memory array, the cell width W may represent and be referred to as a memory cell pitch in the memory array along the X-direction, and the cell height H may represent and be referred to as a memory cell pitch in the memory array along the Y-direction.

The cell size of the two-port SRAM cell 100′ is W×H, in which the cell width W is about 4 times a poly pitch (e.g., a center-to-center distance between two adjacent gate structures along the X-direction) and the cell height H is about 2 times an isolation pitch (e.g., a center-to-center distance between two adjacent STI features along the Y-direction). Denoting an area of one poly pitch times one isolation pitch as a unit area, each unit area includes an intersection of a gate structure and an active region, and the two-port SRAM cell 100′ utilizes a cell size of about 8 times a unit area in accommodating the seven transistors, namely the transistors PG-1, PG-2, PU-1, PU-2, PD-1, PD-2, and R-PG. The area utilization at the device layer of the SRAM cell 100′ is considered efficient as there is only one unit area not utilized for forming a functional transistor but hosting an intersection of a CPODE feature and an active region instead.

FIG. 8 also illustrates dimensions of some features in the layout of the SRAM cell 100. The active region 102 has a width denoted as A1, the active region 104 has a width denoted as A2. Each of the gate structures 110-120 has a critical dimension (CD) or gate width denoted as G. In the illustrated embodiment, the gate structures 110-120 are evenly distributed along the X-direction. An edge-to-edge (or center-to-center) distance between two adjacent gate structures along the X-direction is a gate pitch (or poly pitch) denoted as P. A distance (along the Y-direction) between opposing edges of the active regions 102, 104 is denoted as D1. A distance (along the Y-direction) between an edge of the active region 102 or 104 and a respective closest edge of the boundary 140 is denoted as D2. Therefore, the cell height H of the SRAM cell 100 is A1+A2+D1+2×D2. In some embodiments, G ranges from about 10 nm to about 20 nm; A1 ranges from about 11 nm to about 35 nm; A2 ranges from about 11 nm to about 35 nm; D1 ranges from about 30 nm to about 80 nm; and D2 ranges from about 15 nm to about 40 nm. A1 and A2 may be the same or different to balance speeds among write-port and read-port. A ratio between A2 and A1 (A2/A1) may range from about 0.3 to about 3.5.

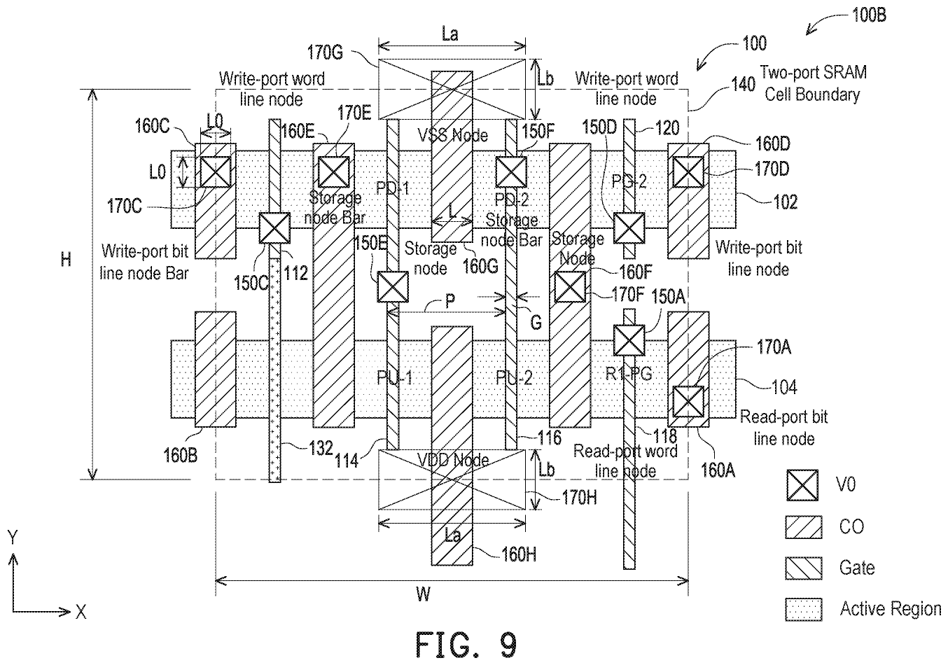

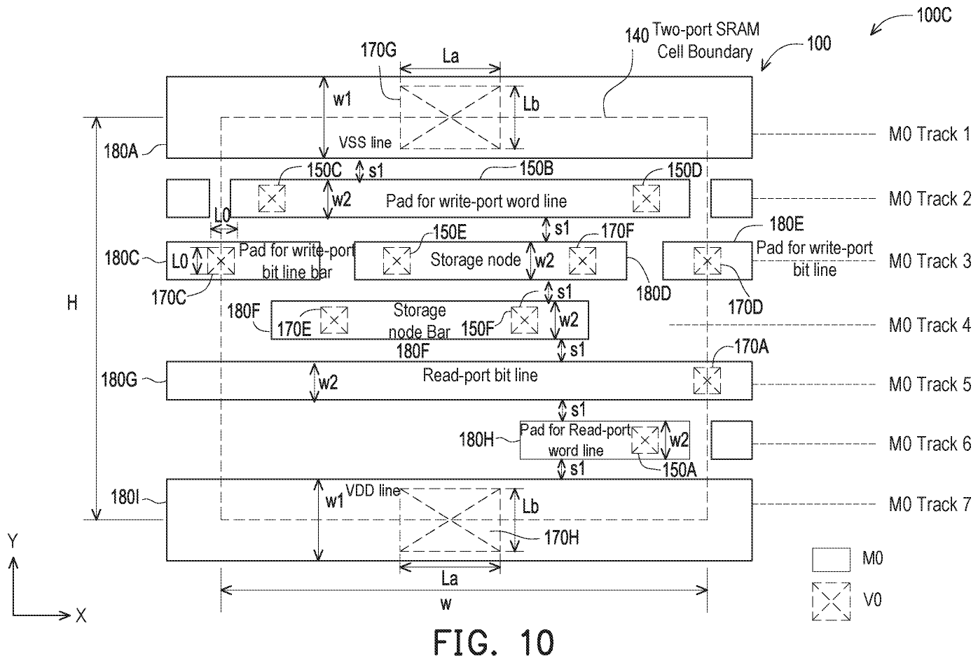

FIG. 9 illustrates a simplified diagrammatic layout 100B′ at the contact level (C0) and the via zero (V0) level of the two-port SRAM cell 100′. Also, for reasons of aiding visual clarity, some features in the layout 100A′ devoted to the device layer (DL) are reproduced in FIG. 9, such as the active regions 102, 104, the gate structures 112-120, the CPODE feature 132, and the cell boundary 140, while numerous other features are omitted in FIG. 9.

A gate contact 150A electrically connects a gate of the read-port pass-gate transistor R-PG (formed by the gate structure 118) to the read-port word line node (R_WL). A gate contact 150C electrically connects a gate of the write-port pass-gate transistor PG-1 (formed by the gate structure 112) to the write-port word line node (W_WL). A gate contact 150D electrically connects a gate of the write-port pass-gate transistor PG-2 (formed by the gate structure 120) to the write-port word line node (W_WL). A gate contact 150E electrically connects a gate of the write-port pull-down transistor PD-1 (formed by the gate structure 114) and a gate of the write-port pull-up transistor PU-1 (also formed by the gate structure 114) to the storage node (SN). A gate contact 150F electrically connects a gate of the write-port pull-down transistor PD-2 (formed by the gate structure 116) and a gate of the write-port pull-up transistor PU-2 (also formed by the gate structure 116) to the complementary storage node (SNB).

A source/drain contact 160A and a source/drain contact via 170A landing thereon electrically connect a source region of the read-port pass-gate transistor R-PG to the read-port bit line node (R_BL). A source/drain contact 160B lands on a source/drain region adjacent to the CPODE feature 132 and stays electrically floating, as there is no corresponding source/drain contact via landing thereon. A source/drain contact 160C and a source/drain contact via 170C landing thereon electrically connect a source region of the write-port pass-gate transistor PG-1 to the write-port complementary bit line node (W_BLB). A source/drain contact 160D and a source/drain contact via 170D landing thereon electrically connect a source region of the write-port pass-gate transistor PG-2 to the write-port bit line node (W_BL). A source/drain contact 160E and a source/drain contact via 170E landing thereon electrically connect a common drain region of the write-port pass-gate transistor PG-1 and the write-port pull-down transistor PD-1 together with a drain region of the write-port pull-up transistor PU-1 to the complementary storage node (SNB). A source/drain contact 160F and a source/drain contact via 170F landing thereon electrically connect a common drain region of the write-port pass-gate transistor PG-2 and the write-port pull-down transistor PD-2 together with a common drain region of the write-port pull-up transistor PU-2 and the read-port pass-gate transistor R-PG to the storage node (SN). A source/drain contact 160G and a source/drain contact via 170G landing thereon electrically connect a common source region of the write-port pull-down transistor PD-1 and the write-port pull-down transistor PD-2 to the electrical ground node VSS. A source/drain contact 160H and a source/drain contact via 170H landing thereon electrically connect a common source region of the write-port pull-up transistor PU-1 and the write-port pull-up transistor PU-2 to the power voltage node VDD. In the illustrated embodiment, the source/drain contacts 160A-H each are elongated and have a longitudinal direction in the Y-direction, which is parallel to the extending directions of gate structures.

Still referring to FIG. 9, the gate contacts 150A/C-F and the source/drain contact vias 170A/C-F may have the same size in a top view. For example, each of the gate contacts 150A/C-F and the source/drain contact vias 170A/C-F may have a square shape with the same edge length L0 in the X-direction and in the Y-direction. Further in the illustrated embodiment, each of the source/drain contacts 160A-H may have the same width L measured in the X-direction, and the edge length L0 may be smaller than the width L. As a comparison, each of the source/drain contact vias 170G and 170H has a larger size, such as a first dimension La measured in the X-direction and a second dimension Lb measured in the Y-direction with La>L0 and Lb>L0. In some embodiments, the first dimension La may be larger than the width L. In furtherance of some embodiments, edges of the source/drain contact vias 170G and 170H may extend beyond outer edges of the gate structure 114 and the gate structure 116. State differently, the first dimension La may be larger than a sum of the poly pitch P and the gate width G (La>P+G). A portion of the gate structure 114 and a portion of the gate structure 116 may be directly under the source/drain contact vias 170G and 170H. In some embodiments, a range of La/L0 is from about 1 to about 5, and a range of Lb/L0 is from about 1 to about 5. In some embodiments, a range of La/G is from about 1 to about 5, and a range of Lb/G is from about 1 to about 5. In some embodiments, a range of La/L is from about 1 to about 5, and a range of Lb/L is from about 1 to about 5. The source/drain contact vias 170G and 170H are electrically connected to the electrical ground node and power voltage node, respectively, whose resistances contribute more impacts to an SRAM cell's speed than other source/drain contact vias and gate contacts. The larger size of the source/drain contact vias 170G and 170H reduces respective source/drain contact via resistance and effectively improves circuit speed.

Also shown in FIG. 9, the storage node SN includes the gate contact 150E and the source/drain contact via 170F positioned on two opposing sides of the gate structure 116. As to discuss in further detail below, a metal line at the M0 level extends in the X-direction to across the gate structure 116 and connects the gate contact 150E and the source/drain contact via 170F. In other words, an M0 metal line hangs over the gate structure 116 and provide the function of cross coupling between the gate contact 150E and the source/drain contact via 170F. Therefore, in the layout 100B′, the gate contact 150E and the source/drain contact via 170F are positioned as being level in the Y-direction, such that a metal line extending in the X-direction may connect both. Similarly, the complementary storage node (storage node bar) SNB includes the gate contact 150F and the source/drain contact via 170E positioned on two opposing sides of the gate structure 114. As to discuss in further detail below, another metal line at the M0 level extends in the X-direction to across the gate structure 114 and connects the gate contact 150F and the source/drain contact via 170E. In other words, another M0 metal line hangs over the gate structure 114 and provide the function of cross coupling between the gate contact 150F and the source/drain contact via 170E. Therefore, in the layout 100B′, the gate contact 150F and the source/drain contact via 170E are positioned as being level in the Y-direction, such that a metal line extending in the X-direction may connect both.

FIG. 10 illustrates a simplified diagrammatic layout 100C′ at the metal zero (M0) level of the two-port SRAM cell 100′. Also, for reasons of aiding visual clarity, the gate contacts 150A/C-F and source/drain contact vias 170A/C-H at the via zero (V0) level are reproduced in FIG. 10, while numerous other features are omitted in FIG. 10.

At the M0 level, the SRAM cell 100′ includes a plurality of metal tracks arranged in parallel. Particularly, in the illustrated embodiment of the layout 100C′, the SRAM cell 100′ includes seven metal tracks arranged in order from first (M0 Track 1) to seventh (M0 Track 7) along the Y-direction. The center lines of the metal tracks are represented by the dotted lines in FIG. 10. A distance between the center lines of the adjacent metal tracks is denoted as the metal track pitch.

One metal track may include a single metal line extending through the entire SRAM cell 100′ along the X-direction. Such a metal line is denoted as a global metal line. Alternatively, one metal track may include one or more metal lines that do not extend through the entire SRAM cell 100′. Such a metal line is denoted as a local metal line, or referred to as an island, a pad, or a landing pad. In the layout 100C′, the first metal track “M0 Track 1” includes a global metal line 180A, which is a VSS line electrically coupled to the source/drain contact via 170G. The VSS line 180A is disposed on the upper boundary line of the SRAM cell 100′ and shared with an adjacent SRAM cell. Disposed on the upper boundary line of the SRAM cell 100′, the source/drain contact via 170G is also shared by the two adjacent SRAM cells. The second metal track “M0 Track 2” includes a local metal line 180B as a pad for the write-port word line (W_WL). The local metal line 180B is fully within the SRAM cell 100′ and electrically connects to the gate contact 150C and the gate contact 150D. The third metal track “M0 Track 3” includes three local metal lines 180C, 180D, and 180E. The local metal line 180C provides a pad for the write-port complimentary bit line (W_BLB). The local metal line 180C extends beyond a left edge of the SRAM cell 100′ and may be shared with an adjacent SRAM cell. The local metal line 180D is fully within the SRAM cell 100′, which belongs to the storage node (SN) and provides cross-coupling between the gate contact 150E and the source/drain contact via 170F. As discussed above, the local metal line 180D crosses over the gate structure 116. The local metal line 180E provides a pad for the write-port bit line (W_BL). The local metal line 180E extends beyond a right edge of the SRAM cell 100 and may be shared with an adjacent SRAM cell. The fourth metal track “M0 Track 4” includes a local metal line 180F, which belongs to the complementary storage node (SNB). The local metal line 180F is fully within the SRAM cell 100′ and provides cross-coupling between the gate contact 150F and the source/drain contact via 170E. As discussed above, the local metal line 180F crosses over the gate structure 114. The fifth metal track “M0 Track 5” includes a global metal line 180G, which is a read-port bit line electrically coupled to the source/drain contact via 170A. The sixth metal track “M0 Track 6” includes a local metal line 180H. The local metal line 180H is fully within the SRAM cell 100′ and provides a pad for the read-port word line (R_WL). The seventh metal track “M0 Track 7” includes a global metal line 1801, which is a VDD line electrically coupled to the source/drain contact via 170H. The VDD line 1801 is disposed on the lower boundary line of the SRAM cell 100′ and may be shared with an adjacent SRAM cell. Disposed on the lower boundary line of the SRAM cell 100′, the source/drain contact via 170H is also shared by the two adjacent SRAM cells.

A width of the VSS line 180A is denoted as w1 with one half of w1 in one SRAM cell and another half of w1 in the adjacent SRAM cell. A width of the VDD line 1801 may be substantially the same as the VSS line 180A with one half of w1 in one SRAM cell and another half of w1 in the adjacent SRAM cell. The other M0 metal lines 180B-H may each have the same width denoted as w2. The spacing between two adjacent M0 metal lines may be uniform and denoted as s1. Thus, the SRAM cell height H equals w1+5*w2+6*s1.

In SRAM device design, the power rails and signal lines are not necessarily all formed on the frontside of the integrated circuit structure but may be distributed on both the frontside and backside of the integrated circuit structure. For example, the integrated circuit structure may include a frontside multilayer interconnect structure (FMLI) and a backside multilayer interconnect structure (BMLI) disposed on the frontside and backside of the integrated circuit structure respectively and configured to connect various components of the pull-up devices, pull-down devices, and pass-gate devices to form the SRAM cells. The configuration is designed with considerations of various factors and parameters, including sizes of various conductive features, packing density, resistance of the conductive features, parasitic capacitances among adjacent conductive features, overlay shifting and processing margins. In the following illustrated embodiments, the power rails and the signal lines are formed on the frontside of the SRAM device, while a portion of the power rails (e.g., one or both of the grounding line (VSS line) and the power line (VDD line)) is also formed on the backside of the SRAM device. Thus, the power rails are formed on both the frontside and the backside of SRAM cells, which are also referred to as dual side power rails.

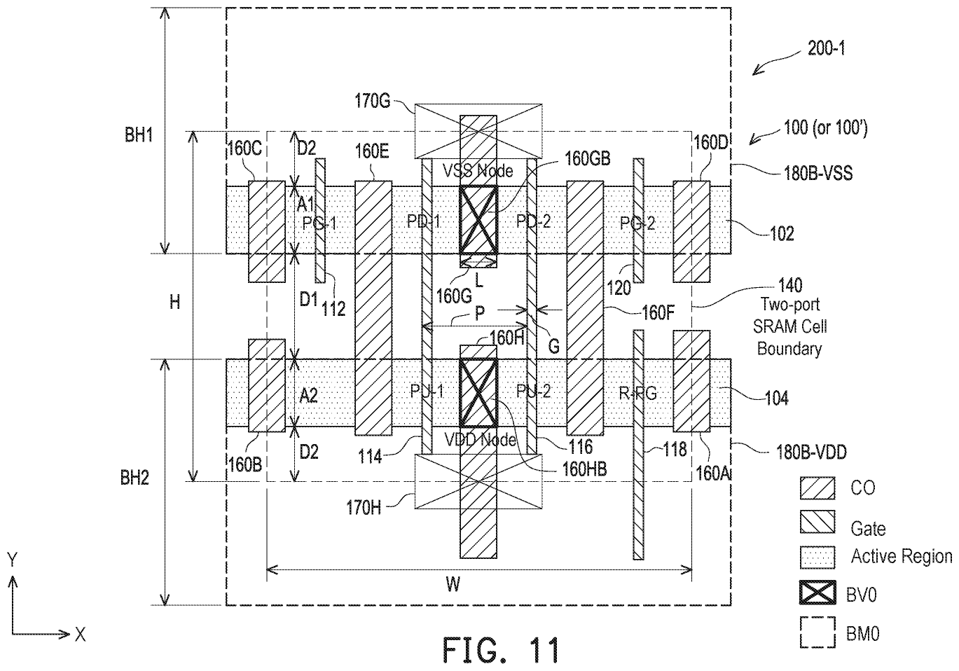

Reference is now made to FIG. 11. FIG. 11 illustrates a simplified diagrammatic layout 200-1 of a portion of the BMLI of the two-port SRAM cell 100 and/or two-port SRAM cell 100′, which includes a backside via zero (BV0) level and a backside metal zero (BM0) level. For reasons of visual clarity and simplicity, active regions, gate structures, source/drain contacts, and two of the source/drain contact vias for power routings (source/drain contact vias 170G and 170H), which are at the frontside of the SRAM device, are overlaying on the layout 200-1. Notably, FIG. 11 illustrates the frontside features in the two-port SRAM cell 100′ as an example, the BMLI layout 200-1 can be applied to the two-port SRAM cell 100 as well.

The BV0 level includes backside vias (or referred to as backside source/drain contacts) 160GB and 160HB. The backside vias 160GB and 160HB can be considered as counterparts of the frontside source/drain contacts 160G and 160H, respectively. Similar to the frontside source/drain contacts 160G and 160H, the backside vias 160GB and 160HB are electrically coupled to the electric ground VSS and power voltage VDD, respectively. The backside vias 160GB and 160HB may have the same width L along the X-direction as the frontside counterparts. In some embodiments, a range of L/G is from about 0.3 to about 2. Different from the frontside counterparts, each of the backside vias 160GB and 160HB has a length along the Y-direction that is substantially the same as the width of the respective active region. This is due to one exemplary backside manufacturing flow in which the backside vias is formed by etching a fin-shape structure in an active region from the backside to form a backside trench and filling the backside trench with conductive materials. Therefore, the backside vias inherit the width of the active region. State differently, the frontside source/drain contact 160G has a length along the Y-direction larger than a width (A1) of the respective active region 102, while the backside via 160GB has a length along the Y-direction substantially the same with the width (A1) of the respective active region 102; the frontside source/drain contact 160H has a length along the Y-direction larger than a width (A2) of the respective active region 104, while the backside via 160HB has a length along the Y-direction substantially the same with the width (A2) of the respective active region 104.

The BM0 level includes backside metal lines 180B-VSS and 180B-VDD arranged in parallel. Each of the backside metal lines 180B-VSS and 180B-VDD is a global metal line extending lengthwise in the X-direction through the entire SRAM cell 100 (or 100′), shared by other SRAM cells in the same row and the abutting SRAM cell along the Y-direction. The backside metal line 180B-VSS electrically connects to the electrical ground VSS and electrically connects to the common source/drain feature of the transistors PD-1 and PD-2 through the backside via 160GB; the backside metal line 180B-VDD electrically connects to the power supply VDD and electrically connects to the common source/drain feature of the transistors PU-1 and PD-2 through the backside via 160HB.

The backside metal line 180B-VSS has a width along the Y-direction denoted as BH1. In the illustrated embodiment, the backside metal line 180B-VSS is shared by an abutting SRAM cell in the Y-direction, and half of its width is located inside the SRAM cell 100 (or 100′) with another half located in the abutting SRAM cell. In the illustrated embodiment, an edge of the backside metal line 180B-VSS is aligned with an inner edge of the active region 102, such that BH1 is twice of a sum of A1 and D2 (BH1=2(A1+D2)). Alternatively, the backside metal line 180B-VSS may not be shared with the abutting SRAM cell along the Y-direction, and the width BH1 may be even smaller than A1. In some embodiments, a range of BH1/H is from about 0.1 to about 1, and a range of BH1/A1 is from about 0.1 to about 6. Similarly, the backside metal line 180B-VDD has a width along the Y-direction denoted as BH2. In the illustrated embodiment, the backside metal line 180B-VDD is shared by an abutting SRAM cell in the Y-direction, and half of its width is located inside the SRAM cell 100 (or 100′) with another half located in the abutting SRAM cell. In the illustrated embodiment, an edge of the backside metal line 180B-VDD is aligned with an inner edge of the active region 104, such that BH2 is twice of a sum of A2 and D2 (BH2=2(A2+D2)). Alternatively, the backside metal line 180B-VDD may not be shared with the abutting SRAM cell along the Y-direction, and the width BH2 may be even smaller than A2. In some embodiments, a range of BH2/H is from about 0.1 to about 1, and a range of BH2/A2 is from about 0.1 to about 6. Further, as A1 and A2 may be the same or different, BH1 and BH2 may be the same or different. In some embodiments, a range of BH1/BH2 is from about 0.3 to about 3.

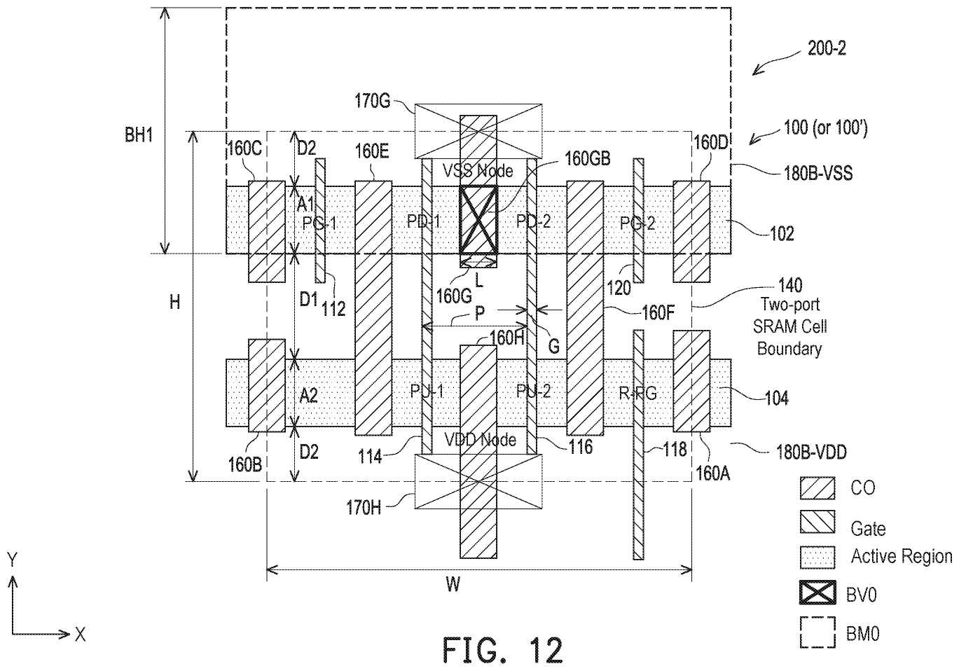

FIG. 12 illustrates an alternative layout 200-2 of a portion of the BMLI of the two-port SRAM cell 100 and/or two-port SRAM cell 100′, which includes a backside via zero (BV0) level and a backside metal zero (BM0) level. For reasons of visual clarity and simplicity, active regions, gate structures, source/drain contacts, and two of the source/drain contact vias for power routings (source/drain contact vias 170G and 170H), which are at the frontside of the SRAM device, are overlaying on the layout 200-2. Notably, FIG. 12 illustrates the frontside features in the two-port SRAM cell 100′ as an example, while the BMLI layout 200-2 can be applied to the two-port SRAM cell 100 as well. Many aspects of the BMLI layout 200-2 are similar to those of the BMLI layout 200-1. Some reference numerals are repeated for ease of understanding. One difference between the BMLI layout 200-2 and the BMLI layout 200-1 is that there are no backside via 160HB and backside metal line 180B-VDD in the BMLI layout 200-2. In other words, the power routing for VDD is relied on the frontside power rails, and the power routing for VSS is backed by both the frontside and the backside power rails. This configuration boots performance of transistors PD-1 and PD-2 and increases write-port speed. The ground bounce on VSS line is also reduced.

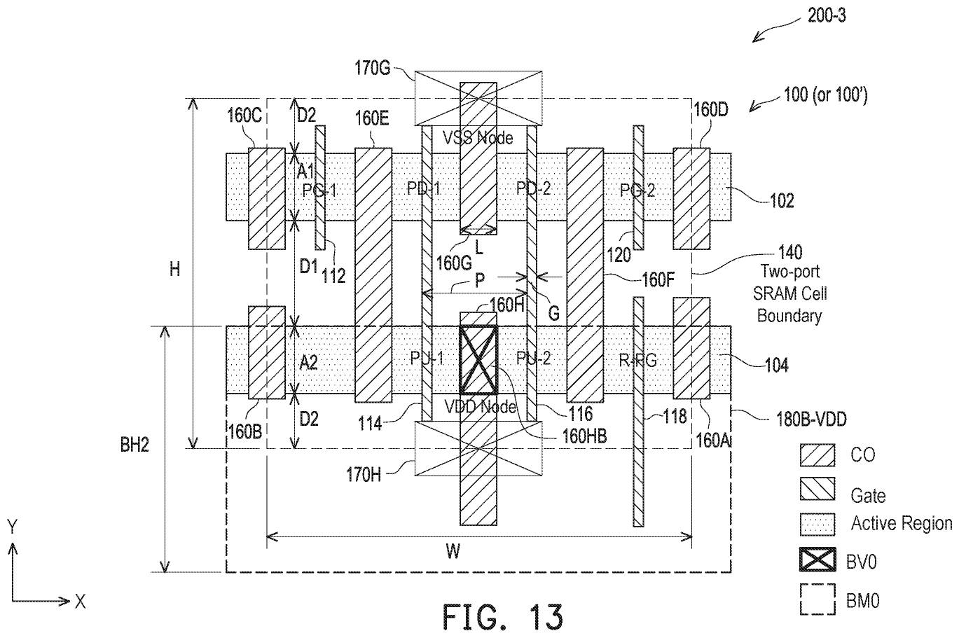

FIG. 13 illustrates an alternative layout 200-3 of a portion of the BMLI of the two-port SRAM cell 100 and/or two-port SRAM cell 100′, which includes a backside via zero (BV0) level and a backside metal zero (BM0) level. For reasons of visual clarity and simplicity, active regions, gate structures, source/drain contacts, and two of the source/drain contact vias for power routings (source/drain contact vias 170G and 170H), which are at the frontside of the SRAM device, are overlaying on the layout 200-3. Notably, FIG. 13 illustrates the frontside features in the two-port SRAM cell 100′ as an example, while the BMLI layout 200-3 can be applied to the two-port SRAM cell 100 as well. Many aspects of the BMLI layout 200-3 are similar to those of the BMLI layout 200-1. Some reference numerals are repeated for ease of understanding. One difference between the BMLI layout 200-3 and the BMLI layout 200-1 is that there are no backside via 160GB and backside metal line 180B-VSS in the BMLI layout 200-3. In other words, the power routing for VSS is relied on the frontside power rails, and the power routing for VDD is backed by both the frontside and the backside power rails. This configuration boots performance of transistors PU-1 and PU-2 and increases read-port speed. The voltage drop on VDD line is also reduced.

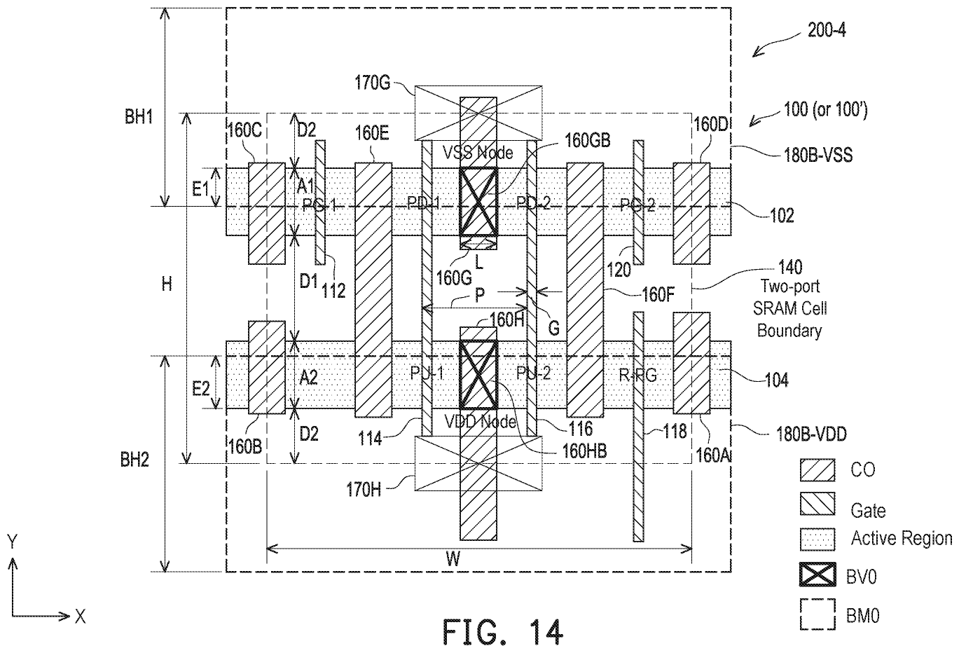

FIG. 14 illustrates an alternative layout 200-4 of a portion of the BMLI of the two-port SRAM cell 100 and/or two-port SRAM cell 100′, which includes a backside via zero (BV0) level and a backside metal zero (BM0) level. For reasons of visual clarity and simplicity, active regions, gate structures, source/drain contacts, and two of the source/drain contact vias for power routings (source/drain contact vias 170G and 170H), which are at the frontside of the SRAM device, are overlaying on the layout 200-4. Notably, FIG. 14 illustrates the frontside features in the two-port SRAM cell 100′ as an example, while the BMLI layout 200-4 can be applied to the two-port SRAM cell 100 as well. Many aspects of the BMLI layout 200-4 are similar to those of the BMLI layout 200-1. Some reference numerals are repeated for ease of understanding. One difference between the BMLI layout 200-4 and the BMLI layout 200-1 is that the backside metal lines 180B-VSS and 180B-VDD partially overlaps with the backside vias 160GB and 160HB along the Y-direction, respectively. In other words, the backside vias 160GB and 160HB partially lands on backside metal lines 180B-VSS and 180B-VDD, respectively. For example, the backside metal line 180B-VSS may overlap with the backside via 160GB for a distance E1 along the Y-direction, in which E1 is less than A1; the backside metal line 180B-VDD may overlap with the backside via 160HB for a distance E2 along the Y-direction, in which E2 is less than A2. In some embodiments, a range of E1/A1 is from about 0.2 to about 1, and a range of E2/A2 is from about 0.2 to about 1. The partial landing of the backside vias on respective backside metal lines reduces parasitic capacitance between the frontside signal lines (e.g., read-port bit line) and the backside power rails and improves SRAM cell performance. Further, the partial overlapping between the backside vias and the backside metal lines can also be applied to the alternative BMLI layouts 200-2 (FIG. 12) and 200-3 (FIG. 13).

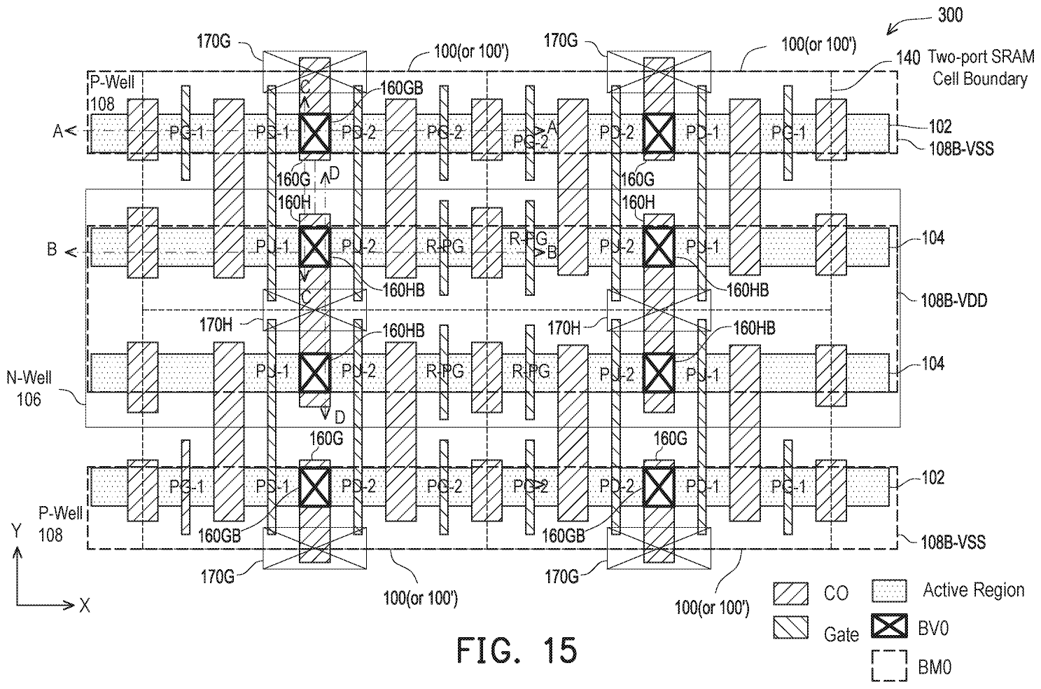

FIG. 15 illustrates a diagrammatic layout of an SRAM array 300 according to the present disclosure. Referring to FIG. 15, a plurality of two-port SRAM cells 100 and/or two-port SRAM cells 100′ are arranged in the X-direction and the Y-direction, forming a 2×2 array of SRAM cells. Each SRAM cell in the array may use the layout of the SRAM cell 100 as depicted in FIG. 4 or the layout of the SRAM cell 100′ as depicted in FIG. 8. In the illustrated embodiment, two adjacent SRAM cells in the X-direction are line symmetric with respect to a common boundary therebetween, and two adjacent SRAM cells in the Y-direction are line symmetric with respect to a common boundary therebetween.

The SRAM array 300 includes well regions 106 and 108 alternately arranged along the Y-direction. In other words, every P-well region 108 is next to an N-well region 106 which is next to another P-well region 108, and this pattern repeats. The frontside source/drain contacts disposed at boundaries of the SRAM cells may be shared by adjacent SRAM cells. In the illustrated embodiment, the source/drain contacts 160H each extend across boundary lines of two abutting SRAM cells along the Y-direction and is shared by these two abutting SRAM cells, therefore tying the VDD nodes of the two abutting SRAM cells together. Similarly, the source/drain contacts 160G may also extend across boundary lines of two abutting SRAM cells along the Y-direction and be shared by these two abutting SRAM cells, therefore tying the VSS nodes of the two abutting SRAM cells together. Each of the frontside source/drain contact vias 170G and 170H is disposed on a boundary line of two abutting SRAM cells and shared by the two abutting SRAM cells. As a comparison, in the depicted embodiment as in FIG. 15, each of the backside vias 160GB and 160HB is within the boundary of a respective SRAM cell and not shared with any adjacent SRAM cells. Yet, the backside metal line 180B-VDD electrically connects the four backside vias 160HB of the SRAM array 300 to the power voltage VDD; the backside metal lines 180B-VSS electrically connect the backside vias 160GB in the same rows to the electrical ground VSS.

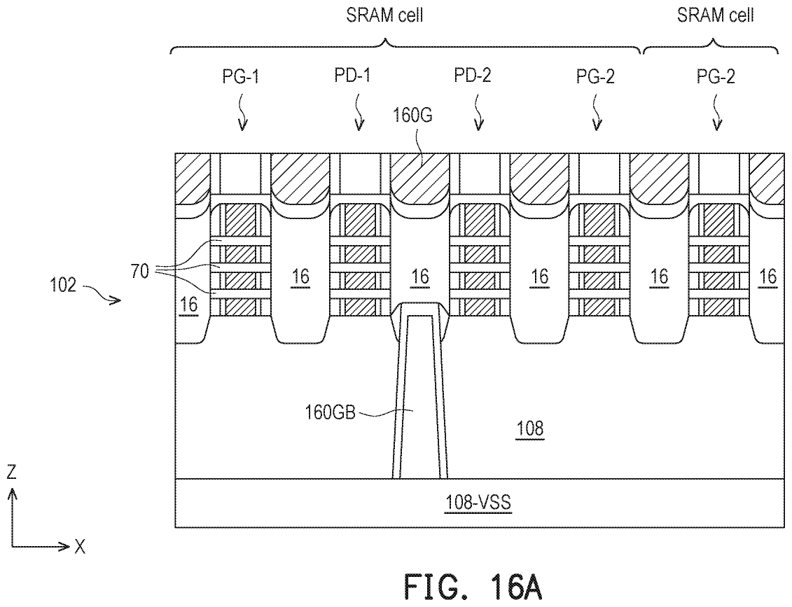

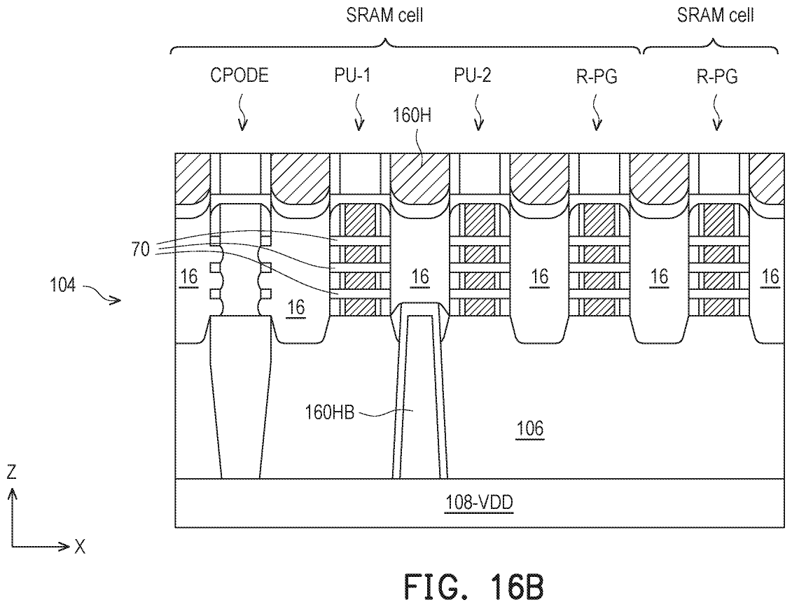

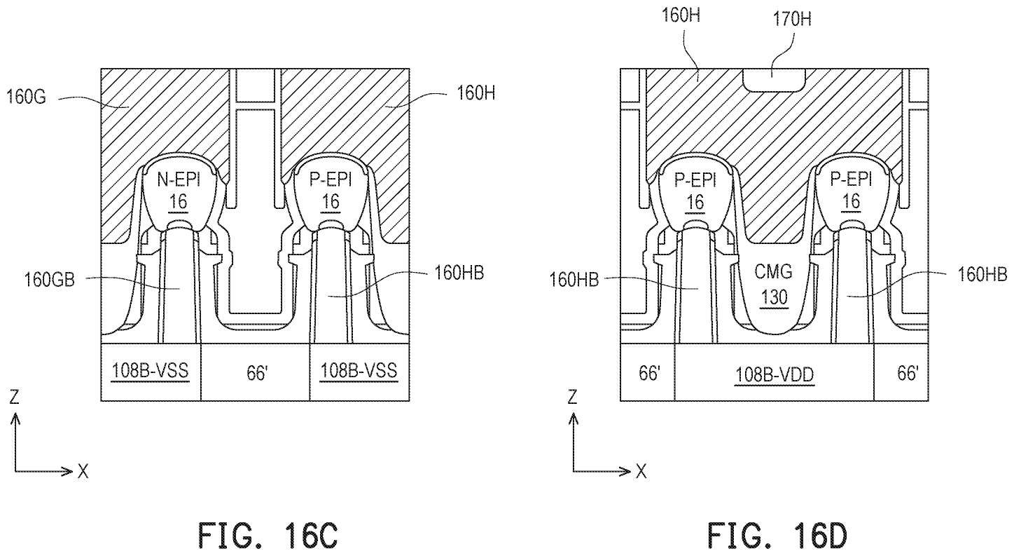

FIG. 16A is a fragmentary diagrammatic cross-sectional view along A-A line of FIG. 15, which cuts the active region 102 along its lengthwise direction; FIG. 16B is a fragmentary diagrammatic cross-sectional view along B-B line of FIG. 15, which cuts the active region 104 along its lengthwise direction; FIG. 16C is a fragmentary diagrammatic cross-sectional view along C-C line of FIG. 15, which cuts source/drain regions within an SRAM cell; FIG. 16D is a fragmentary diagrammatic cross-sectional view along D-D line of FIG. 15, which cuts the source/drain regions across a boundary line between two abutting SRAM cells.

Referring to FIGS. 16A-D collectively, each of the active regions 102 and 104 extends continuously through the SRAM cells in the same row of the array 300, which includes channel regions that is comprised of the nanostructures 70 and source/drain features 16 abut the ends of the nanostructures 70. The gate structures wrap around the nanostructures 70 and form the transistors PG-1, PD1, PD-2, PG-2 in the active region 102 and the transistors PU-1, PU-2, R-PG in the active region 104. The active region 104 is disposed over the N-well 106, and the active region 102 is disposed over the P-well 108. The source/drain features 16 formed on the active region 104 is p-type epitaxial features, and the source/drain features 16 formed on the active region 102 is n-type epitaxial features. The source/drain contact 160G electrically couples the common source/drain feature 16 of the transistors PD-1 and PD2 to the frontside VSS line; the backside via 160GB electrically couples the common source/drain feature 16 of the transistors PD-1 and PD-2 to the backside VSS line (e.g., backside M0 line 108B-VSS). The source/drain contact 160H electrically couples the common source/drain feature 16 of the transistors PU-1 and PU-2 to the frontside VDD line; the backside via 160HB electrically couples the common source/drain feature 16 of the transistors PU-1 and PU-2 to the backside VDD line (e.g., backside M0 line 108B-VDD). An edge of the backside metal line 108B-VDD may be aligned with an edge of the backside via 160HB; an edge of the backside meal line 108B-VSS may be aligned with an edge of the backside via 160GB. On the backside of the SRAM array, the backside metal lines 108B-VDD and 108B-VSS are separated by the backside dielectric feature 66′. In the depicted embodiment, each of the backside vias 160GB and 160HB is within the boundary of a respective SRAM cell and not shared with any adjacent SRAM cells. The backside metal line 108B-VDD electrically connects two backside vias 160HB in two abutting SRAM cells.

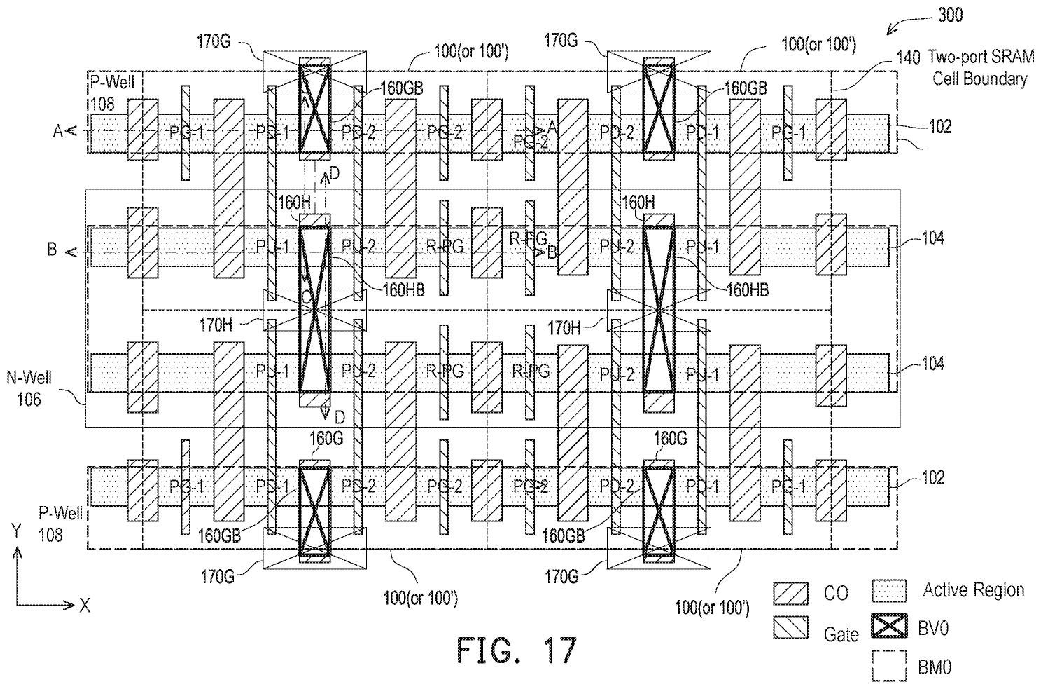

FIG. 17 illustrates an alternative diagrammatic layout of the SRAM array 300 according to the present disclosure. Many aspects of the alternative layout of FIG. 17 are similar to those of the layout of FIG. 15. Some reference numerals are repeated for ease of understanding. One difference between the embodiments in FIGS. 15 and 17 is that the middle two backside vias 160HB are merged together as one longer backside via 160HB in FIG. 17. The merged backside via 160HB crosses over two active regions 104 and straddles a CMG feature therebetween (e.g., the CMG feature 130 of FIG. 8). Upper edge of the merged backside via 160HB aligns with an edge of the upper one of the two active regions 104, and lower edge of the merged backside via aligns with an edge of the lower one of the two active regions 104. Thus, the length of the merged backside via 160HB along the Y-direction is 2*A2+D, in which A2 is the width of the active region 104 and D is the distance between the two active regions 104.

With the ever-decreasing geometry size, the width (e.g., A2) of the active regions has become so small such that the backside via holes consequently have a small opening and a large aspect ratio. The small opening and the large aspect ratio reduce the process window for filling conductive materials, which may lead to incomplete via formation and overlay error. Further, expanding the dimensions of the backside vias along the X-direction and/or the Y-direction may not be feasible, as the etching of an expanded via hole may also etch through dielectric layer between the via hole and the gate structures and cause metal gate protrusion and device malfunction. The otherwise two separated backside vias may form one continuous backside via straddling a CMG feature. The expanded opening and the reduced-aspect-ratio of via holes enlarge the process window, reduce difficulty of filling conductive material(s) in high-aspect-ratio via holes, and mitigate overlaying inaccuracy.

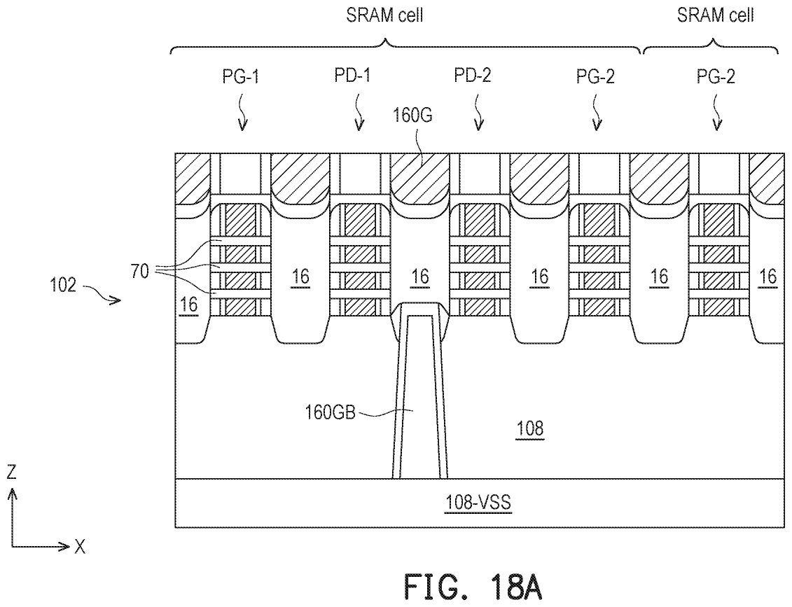

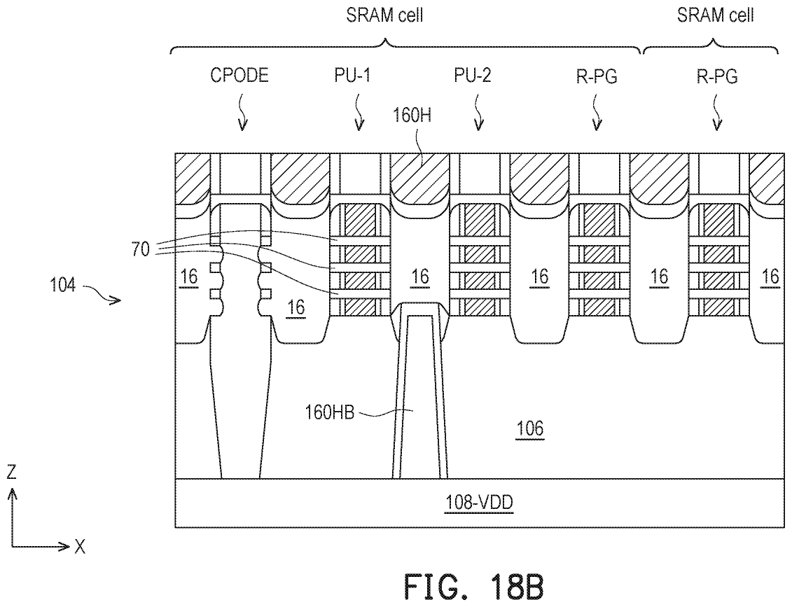

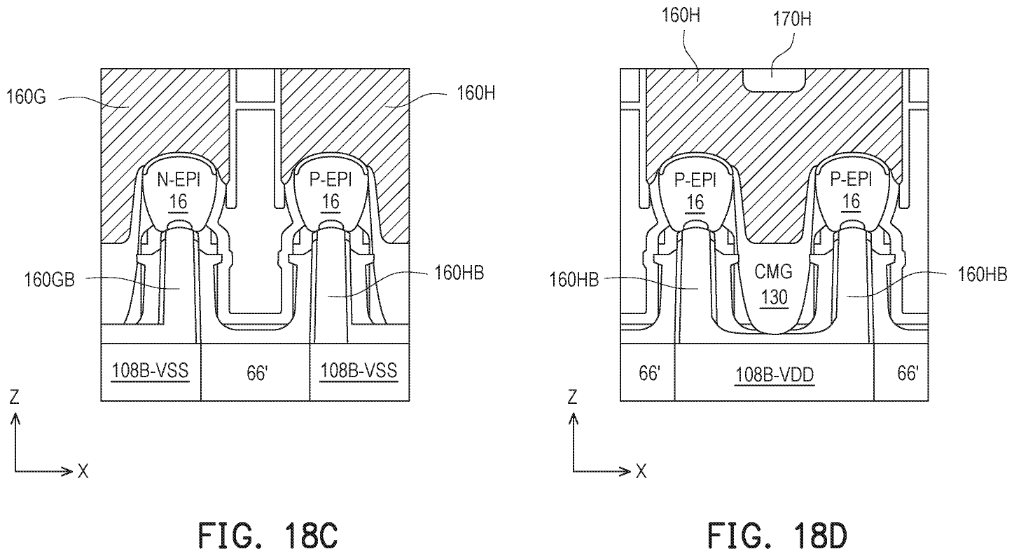

FIG. 18A is a fragmentary diagrammatic cross-sectional view along A-A line of FIG. 17, which cuts the active region 102 along its lengthwise direction; FIG. 18B is a fragmentary diagrammatic cross-sectional view along B-B line of FIG. 17, which cuts the active region 104 along its lengthwise direction; FIG. 18C is a fragmentary diagrammatic cross-sectional view along C-C line of FIG. 17, which cuts source/drain regions within an SRAM cell; FIG. 18D is a fragmentary diagrammatic cross-sectional view along D-D line of FIG. 17, which cuts the source/drain regions across a boundary line between two abutting SRAM cells. Many aspects of the embodiment of FIGS. 18A-D are similar to those of the FIGS. 16A-D. Some reference numerals are repeated for ease of understanding. One difference is that in FIGS. 18A-D, the merged backside via 160HB has two leg portions filling the two via holes on two sides of the CMG feature 130 and a center portion expanding over the CMG feature 130 and connecting the two leg portions. It can also be considered as a conductive structure including a first backside via formed on the backside of the left active region, a second backside via formed on the backside of the right active region, and a conductive feature connecting the first and second backside vias and across the CMG feature 130.

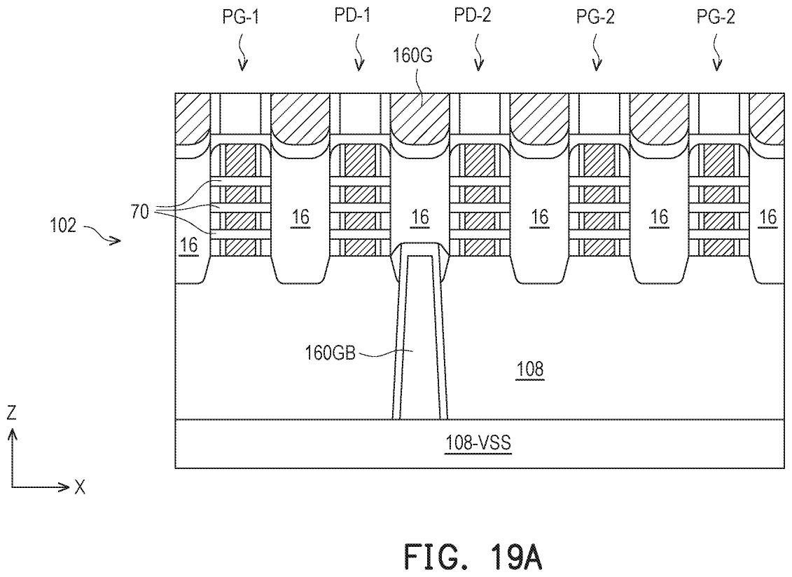

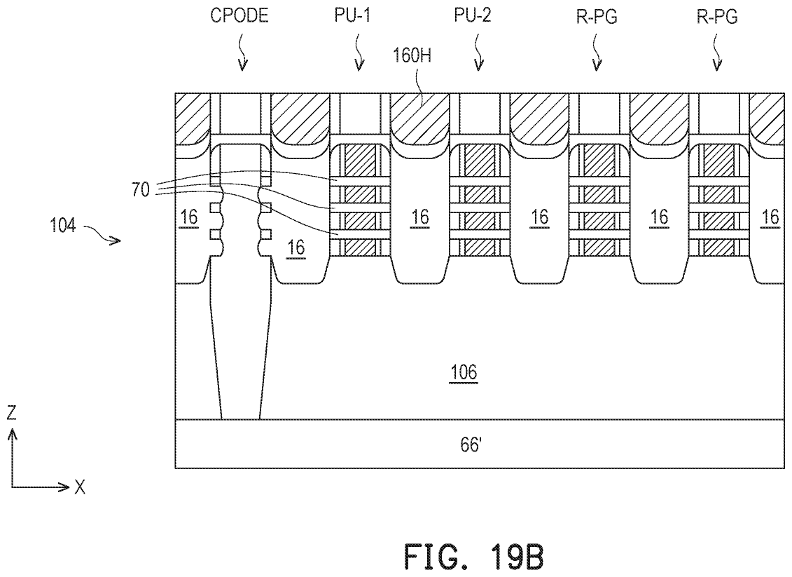

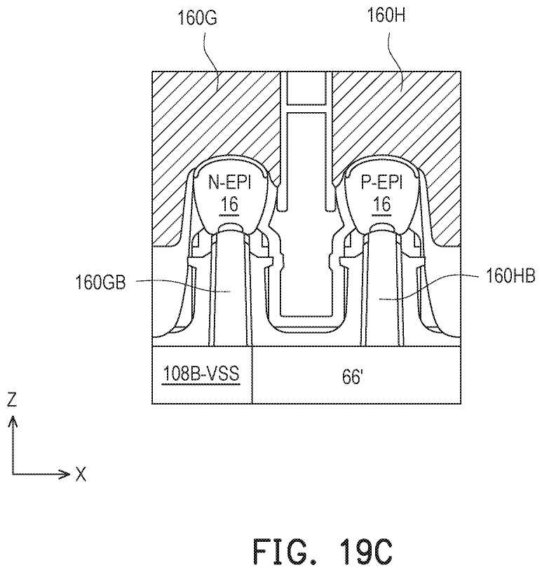

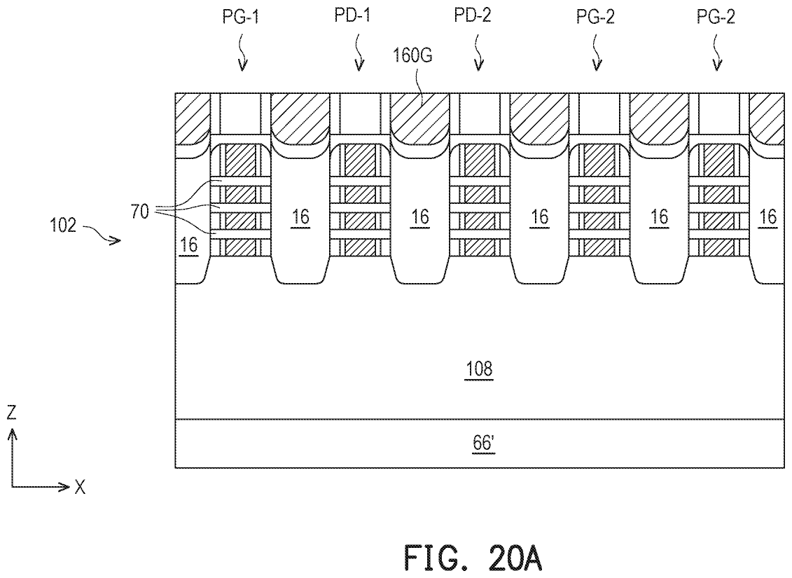

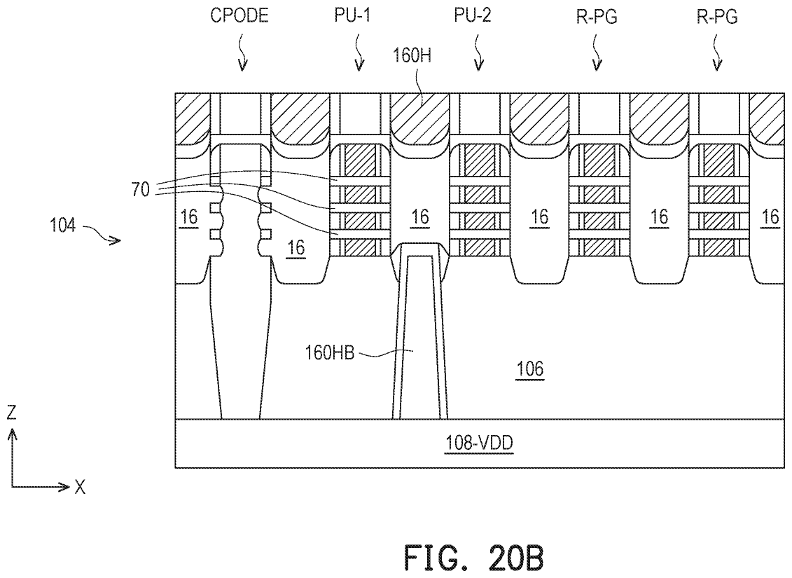

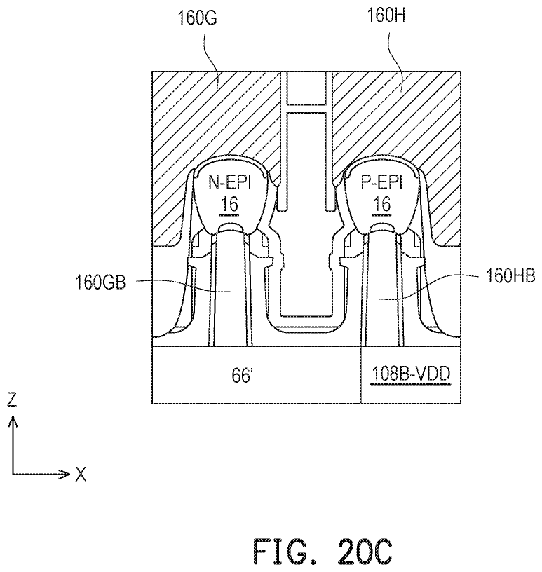

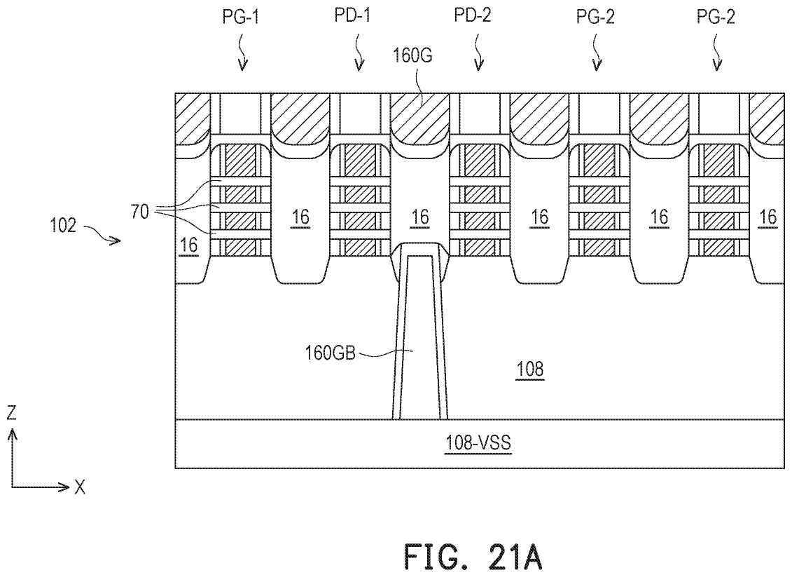

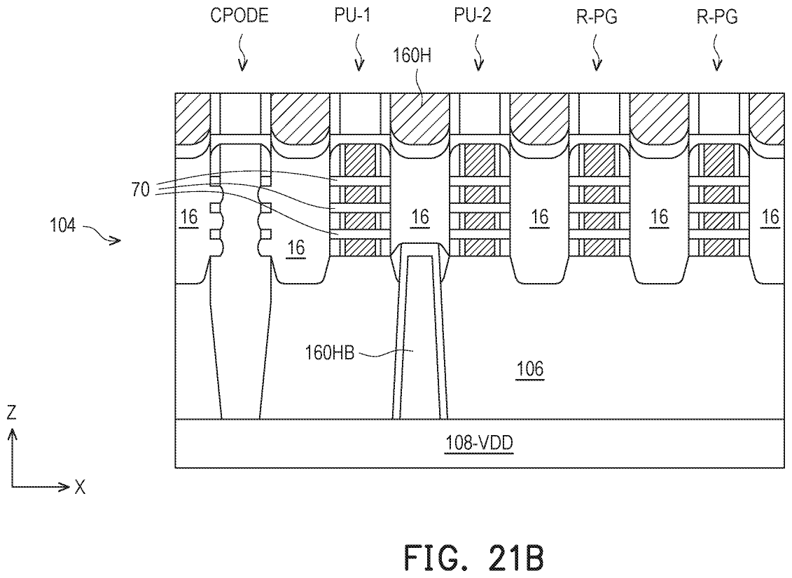

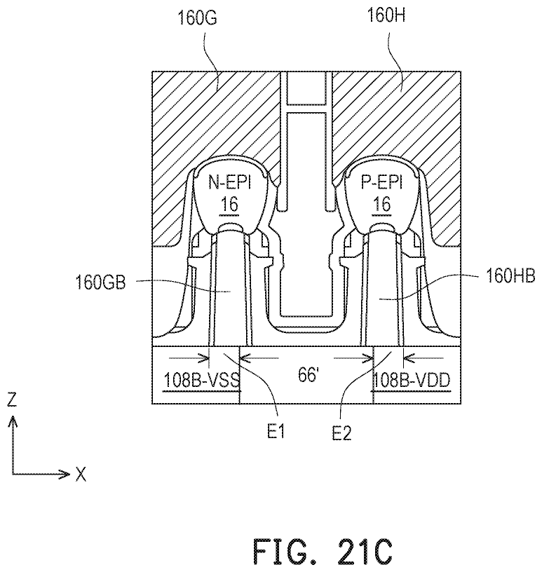

FIGS. 19A-C illustrate alternative cross-sectional views along A-A, B-B, C-C lines of the SRAM array 300, respectively. The backside power rails in the embodiment of FIGS. 19A-C are similar to the one illustrated in FIG. 12, which include backside VSS lines but no backside VDD lines. The area in accommodation of the backside metal line 108B-VDD is filled with the backside dielectric structure 66′ instead. FIGS. 20A-C illustrate alternative cross-sectional views along A-A, B-B, C-C lines of the SRAM array 300, respectively. The backside power rails in the embodiment of FIGS. 20A-C are similar to the one illustrated in FIG. 13, which include backside VDD lines but no backside VSS lines. The area in accommodation of the backside metal line 108B-VSS is filled with the backside dielectric structure 66′ instead. FIGS. 21A-C illustrate alternative cross-sectional views along A-A, B-B, C-C lines of the SRAM array 300, respectively. The backside power rails in the embodiment of FIGS. 21A-C are similar to the one illustrated in FIG. 14, which include backside VSS lines and backside VDD lines partially overlapped with respective backside vias (e.g., a distance E1 and a distance E2 as illustrated in FIG. 21C).

The multi-port SRAM cells and the corresponding layouts illustrated in various exemplary embodiments of the present disclosure provide better cell area utilization and reduced power rail resistance by implementing dual side power rails. Further, embodiments of the present disclosure can be readily integrated into existing semiconductor manufacturing processes.

In one exemplary aspect, the present disclosure is directed to a memory cell. The memory cell includes first and second active regions and first and second gate structures. Each of the first and second active regions extends lengthwise in a first direction. Each of the first and second gate structures extends lengthwise in a second direction that is perpendicular to the first direction. The first gate structure engages the first and second active regions in forming a first pull-down transistor and a first pull-up transistor, respectively. The second gate structure engages the first and second active regions in forming a second pull-down transistor and a second pull-up transistor, respectively. The memory cell also includes a first frontside source/drain contact disposed above and electrically coupled to a first common source/drain region of the first and second pull-down transistors, the first common source/drain region being disposed on the first active region, a first backside via disposed under and electrically coupled to the first common source/drain region, and a first backside metal line disposed under and electrically coupled to the first backside via. In some embodiments, the first backside via electrically couples to an electrical ground of the memory cell. In some embodiments, a width of the first backside via measured in the second direction equals a width of the first active region measured in the second direction. In some embodiments, an edge of the first backside metal line aligns with an edge of the first active region. In some embodiments, the first backside metal line partially overlaps with the first active region in a top view of the memory cell. In some embodiments, the memory cell also includes a second frontside source/drain contact disposed above and electrically coupled to a second common source/drain region of the first and second pull-up transistors, the second common source/drain region being disposed on the second active region, a second backside via disposed under and electrically coupled to the second common source/drain region, and a second backside metal line disposed under and electrically coupled to the second backside via. In some embodiments, the first backside metal line electrically couples to an electrical ground of the memory cell, and the second backside metal line electrically couples to a power voltage of the memory cell. In some embodiments, the first backside metal line and the second backside metal line have different widths.

In another exemplary aspect, the present disclosure is directed to a memory cell. The memory cell includes first and second active regions and first and second gate structures. Each of the first and second active regions extends lengthwise in a first direction. Each of the first and second gate structures extends lengthwise in a second direction that is perpendicular to the first direction. The first gate structure engages the first and second active regions in forming a first pull-down transistor and a first pull-up transistor, respectively. The second gate structure engages the first and second active regions in forming a second pull-down transistor and a second pull-up transistor, respectively. The memory cell also includes a first frontside source/drain contact disposed above and electrically coupled to a first common source/drain region of the first and second pull-up transistors, the first common source/drain region being disposed on the second active region, a first backside via disposed under and electrically coupled to the first common source/drain region, and a first backside metal line disposed under and electrically coupled to the first backside via. In some embodiments, the first backside via electrically couples to a power voltage of the memory cell. In some embodiments, a width of the first backside via measured in the second direction equals a width of the second active region measured in the second direction. In some embodiments, an edge of the first backside metal line aligns with an edge of the second active region. In some embodiments, the first backside metal line partially overlaps with the second active region in a top view of the memory cell. In some embodiments, the memory cell also includes a second frontside source/drain contact disposed above and electrically coupled to a second common source/drain region of the first and second pull-down transistors, the second common source/drain region being disposed on the first active region, a second backside via disposed under and electrically coupled to the second common source/drain region, and a second backside metal line disposed under and electrically coupled to the second backside via. In some embodiments, the first backside metal line electrically couples to a power voltage of the memory cell, and the second backside metal line electrically couples to an electrical ground of the memory cell. In some embodiments, the memory cell also includes a first frontside source/drain contact via disposed above and electrically coupled to the first frontside source/drain contact, the first frontside source/drain contact via and the first backside via having no overlapping portions in a top view of the memory cell.

In yet another exemplary aspect, the present disclosure is directed to a memory array. The memory array includes a first two-port memory cell and a second two-port memory cell. The first two-port memory cell includes a first write port that includes a first pull-up transistor and a second pull-up transistor, and a first read port. The second two-port memory cell includes a second write port that includes a third pull-up transistor and a fourth pull-up transistor, and a second read port. The memory array also includes a frontside source/drain contact electrically coupled to the first, second, third, and fourth pull-up transistors, and a backside source/drain contact disposed directly under the frontside source/drain contact and electrically coupled to the first, second, third, and fourth pull-up transistors. In some embodiments, the memory array also includes a dielectric feature having a first sidewall abutting gate structures of the first and second pull-up transistors and a second sidewall abutting gate structures of the third and fourth pull-up transistors, the backside source/drain contact straddling the dielectric feature. In some embodiments, the memory array also includes a backside metal line disposed directly under the backside source/drain contact and electrically coupled to the backside source/drain contact, a portion of the backside metal line being directly under the first read port and the second read port. In some embodiments, a first edge of the backside metal line aligns with a first edge of the backside source/drain contact, and a second edge of the backside metal line aligns with a second edge of the backside source/drain contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory cell, comprising:
first and second active regions, wherein each of the first and second active regions extends lengthwise in a first direction;
first and second gate structures, wherein each of the first and second gate structures extends lengthwise in a second direction that is perpendicular to the first direction, the first gate structure engages the first and second active regions in forming a first pull-down transistor and a first pull-up transistor, respectively, and the second gate structure engages the first and second active regions in forming a second pull-down transistor and a second pull-up transistor, respectively;
a first frontside source/drain contact disposed above and electrically coupled to a first common source/drain region of the first and second pull-down transistors, wherein the first common source/drain region is disposed on the first active region;
a first backside via disposed under and electrically coupled to the first common source/drain region; and
a first backside metal line disposed under and electrically coupled to the first backside via.

2. The memory cell of claim 1, wherein the first backside via electrically couples to an electrical ground of the memory cell.

3. The memory cell of claim 1, wherein a width of the first backside via measured in the second direction equals a width of the first active region measured in the second direction.

4. The memory cell of claim 1, wherein an edge of the first backside metal line aligns with an edge of the first active region.

5. The memory cell of claim 1, wherein the first backside metal line partially overlaps with the first active region in a top view of the memory cell.

6. The memory cell of claim 1, further comprising:
a second frontside source/drain contact disposed above and electrically coupled to a second common source/drain region of the first and second pull-up transistors, wherein the second common source/drain region is disposed on the second active region;
a second backside via disposed under and electrically coupled to the second common source/drain region; and
a second backside metal line disposed under and electrically coupled to the second backside via.

7. The memory cell of claim 6, wherein the first backside metal line electrically couples to an electrical ground of the memory cell, and the second backside metal line electrically couples to a power voltage of the memory cell.

8. The memory cell of claim 6, wherein the first backside metal line and the second backside metal line have different widths.

9. A memory cell, comprising:
first and second active regions, wherein each of the first and second active regions extends lengthwise in a first direction;
first and second gate structures, wherein each of the first and second gate structures extends lengthwise in a second direction that is perpendicular to the first direction, the first gate structure engages the first and second active regions in forming a first pull-down transistor and a first pull-up transistor, respectively, and the second gate structure engages the first and second active regions in forming a second pull-down transistor and a second pull-up transistor, respectively;
a first frontside source/drain contact disposed above and electrically coupled to a first common source/drain region of the first and second pull-up transistors, wherein the first common source/drain region is disposed on the second active region;
a first backside via disposed under and electrically coupled to the first common source/drain region; and
a first backside metal line disposed under and electrically coupled to the first backside via.

10. The memory cell of claim 9, wherein the first backside via electrically couples to a power voltage of the memory cell.

11. The memory cell of claim 9, wherein a width of the first backside via measured in the second direction equals a width of the second active region measured in the second direction.

12. The memory cell of claim 9, wherein an edge of the first backside metal line aligns with an edge of the second active region.

13. The memory cell of claim 9, wherein the first backside metal line partially overlaps with the second active region in a top view of the memory cell.

14. The memory cell of claim 9, further comprising:
a second frontside source/drain contact disposed above and electrically coupled to a second common source/drain region of the first and second pull-down transistors, wherein the second common source/drain region is disposed on the first active region;
a second backside via disposed under and electrically coupled to the second common source/drain region; and
a second backside metal line disposed under and electrically coupled to the second backside via.

15. The memory cell of claim 14, wherein the first backside metal line electrically couples to a power voltage of the memory cell, and the second backside metal line electrically couples to an electrical ground of the memory cell.

16. The memory cell of claim 14, further comprising:
a first frontside source/drain contact via disposed above and electrically coupled to the first frontside source/drain contact, wherein the first frontside source/drain contact via and the first backside via have no overlapping portions in a top view of the memory cell.

17. A memory array, comprising:
a first two-port memory cell including:
a first write port, wherein the first write port includes a first pull-up transistor and a second pull-up transistor; and
a first read port;
a second two-port memory cell including:
a second write port, wherein the second write port includes a third pull-up transistor and a fourth pull-up transistor; and
a second read port;
a frontside source/drain contact electrically coupled to the first, second, third, and fourth pull-up transistors; and
a backside source/drain contact disposed directly under the frontside source/drain contact and electrically coupled to the first, second, third, and fourth pull-up transistors.

18. The memory array of claim 17, further comprising:
a dielectric feature having a first sidewall abutting gate structures of the first and second pull-up transistors and a second sidewall abutting gate structures of the third and fourth pull-up transistors,
wherein the backside source/drain contact straddles the dielectric feature.

19. The memory array of claim 17, further comprising:
a backside metal line disposed directly under the backside source/drain contact and electrically coupled to the backside source/drain contact, wherein a portion of the backside metal line is directly under the first read port and the second read port.

20. The memory array of claim 19, wherein a first edge of the backside metal line aligns with a first edge of the backside source/drain contact, and a second edge of the backside metal line aligns with a second edge of the backside source/drain contact.
